(19) United States
(12) Patent Application Publication
(10) Pub. No.: US 2025/0307507 A1
(43) Pub. Date: Oct. 2, 2025

(54) TECHNIQUES FOR USING INVERSE DESIGN FOR COMBINED OPTIMIZATION OF OPTICAL AND ELECTRICAL COMPONENTS IN AN OPTOELECTRONIC MODULATOR

(71) Applicant: X Development LLC, Mountain View, CA (US)

(72) Inventors: Brian Adolf, San Mateo, CA (US); Yi-Kuei Ryan Wu, San Jose, CA (US); Ian Williamson, Palo Alto, CA (US); Philip Watson, Felton, CA (US)

(21) Appl. No.: 19/091,369

(22) Filed: Mar. 26, 2025

Related U.S. Application Data
(60) Provisional application No. 63/573,393, filed on Apr. 2, 2024.

(51) Int. Cl. G06F 30/32

(52) U.S. Cl. CPC G06F 30/32

(57) ABSTRACT

In some embodiments, a computer-implemented method for creating a design for an optoelectronic modulator device is provided. A computing system determines an initial design that includes optical structural parameters and electrical structural parameters for a design region. The computing system simulates electrical performance based on the electrical structural parameters to adjust optical characteristics of the optical structural parameters. The computing system simulates optical performance of the optical structural parameters having the adjusted optical characteristics to generate a performance loss value. The computing system determines a loss metric based on the performance loss value. The computing system backpropagates the loss metric to determine a structural gradient. The computing system revises at least one of the optical structural parameters and the electrical structural parameters based at least in part on the structural gradient to create an updated initial design.

### CROSS-REFERENCE(S) TO RELATED APPLICATION(S)

This application claims the benefit of Provisional Application No. 63/573,393, filed Apr. 2, 2024, the entire disclosure of which is hereby incorporated by reference herein for all purposes.

### TECHNICAL FIELD

This disclosure relates generally to photonic devices, and in particular but not exclusively, relates to optoelectronic modulators.

### BACKGROUND

Fiber-optic communication is typically employed to transmit information from one place to another via light that has been modulated to carry the information. For example, many telecommunication companies use optical fiber to transmit telephone signals, internet communication, and cable television signals. At a transmitting side, information is modulated onto a carrier beam that is transmitted via the optical fiber. At a receiving side, an optoelectronic photodetector and related circuitry is used to detect the signal and decode the information.

### BRIEF SUMMARY

In some embodiments, a non-transitory computer-readable medium having logic stored thereon is provided. The logic, in response to execution by one or more processors of a computing system, causes the computing system to perform actions for creating a design for an optoelectronic modulator device. The actions comprise determining, by the computing system, an initial design that includes optical structural parameters and electrical structural parameters for a design region; simulating, by the computing system, electrical performance based on the electrical structural parameters to adjust optical characteristics of the optical structural parameters; simulating, by the computing system, optical performance of the optical structural parameters having the adjusted optical characteristics to generate a performance loss value; determining, by the computing system, a loss metric based on the performance loss value; backpropagating, by the computing system, the loss metric to determine a structural gradient; and revising, by the computing system, at least one of the optical structural parameters and the electrical structural parameters based at least in part on the structural gradient to create an updated initial design.

In some embodiments, a computer-implemented method for creating a design for an optoelectronic modulator device is provided. A computing system determines an initial design that includes optical structural parameters and electrical structural parameters for a design region. The computing system simulates electrical performance based on the electrical structural parameters to adjust optical characteristics of the optical structural parameters. The computing system simulates optical performance of the optical structural parameters having the adjusted optical characteristics to generate a performance loss value. The computing system determines a loss metric based on the performance loss value. The computing system backpropagates the loss metric to determine a structural gradient. The computing system revises at least one of the optical structural parameters and the electrical structural parameters based at least in part on the structural gradient to create an updated initial design.

In some embodiments, a non-transitory computer-readable medium having a description stored thereon is provided. The description represents structures within a design region of an optoelectronic modulator device. The description is determined by: determining, by a computing system, an initial design that includes optical structural parameters and electrical structural parameters for the design region; simulating, by the computing system, electrical performance based on the electrical structural parameters to adjust optical characteristics of the optical structural parameters; simulating, by the computing system, optical performance of the optical structural parameters having the adjusted optical characteristics to generate a performance loss value; determining, by the computing system, a loss metric based on the performance loss value; backpropagating, by the computing system, the loss metric to determine a structural gradient; and revising, by the computing system, at least one of the optical structural parameters and the electrical structural parameters based at least in part on the structural gradient to create an updated initial design.

### BRIEF DESCRIPTION OF THE SEVERAL VIEWS OF THE DRAWINGS

Non-limiting and non-exhaustive embodiments of the invention are described with reference to the following figures, wherein like reference numerals refer to like parts throughout the various views unless otherwise specified. Not all instances of an element are necessarily labeled so as not to clutter the drawings where appropriate. The drawings are not necessarily to scale, emphasis instead being placed upon illustrating the principles being described. To easily identify the discussion of any particular element or act, the most significant digit or digits in a reference number refer to the figure number in which that element is first introduced.

FIG. 1 is a functional block diagram illustrating a non-limiting example embodiment of a system for optical communication between two optical communication devices via an optical signal, according to various aspects of the present disclosure.

FIG. 2A-FIG. 2D illustrate different views of a non-limiting example embodiment of a photonic demultiplexer, according to various aspects of the present disclosure.

FIG. 3A and FIG. 3B illustrate a more detailed cross-sectional view of a dispersive region of a non-limiting example embodiment of a photonic demultiplexer, according to various aspects of the present disclosure.

FIG. 4 illustrates a non-limiting example of a modulator device used in embodiments of the present disclosure.

FIG. 5 is a top-down view of one non-limiting example of a phase shifter that uses the electrical field generated by a transmission line proximate to a waveguide to adjust the phase of an optical signal in the waveguide.

FIG. 6A is a top-down view of a non-limiting example of a carrier depletion modulator device that uses an interdigitated pattern.

FIG. 6B is a cross-sectional view of a non-limiting example of a carrier depletion modulator device that uses a horizontally arranged diode.

FIG. 6C is a cross-sectional view of a non-limiting example of a carrier depletion modulator device that uses a vertically arranged diode.

FIG. 7A-FIG. 7C are schematic illustrations of a non-limiting example embodiment of a design of an optically active region and an electrically active region of a modulator device obtained via inverse design and/or shape optimization according to various aspects of the present disclosure.

FIG. 8 is a functional block diagram illustrating a non-limiting example embodiment of a system for generating a design of a photonic integrated circuit, according to various aspects of the present disclosure.

FIG. 9A-FIG. 9C respectively illustrate non-limiting example embodiments of an initial set up of a simulated environment describing a photonic device, performing an operational simulation of the photonic device within the simulated environment, and performing an adjoint simulation of the photonic device within the simulated environment according to various aspects of the present disclosure.

FIG. 10A is a flow chart illustrating example time steps for an operational simulation and an adjoint simulation, in accordance with various aspects of the present disclosure.

FIG. 10B is a chart illustrating the relationship between the update operation for the operational simulation and the adjoint simulation (e.g., backpropagation), in accordance with an embodiment of the present disclosure.

FIG. 11A and FIG. 11B illustrate a non-limiting example embodiment of an eye diagram according to various aspects of the present disclosure.

FIG. 12 is a flowchart that illustrates a non-limiting example embodiment of a method for generating a design of physical device such as a photonic integrated circuit, in accordance with various aspects of the present disclosure.

### DETAILED DESCRIPTION

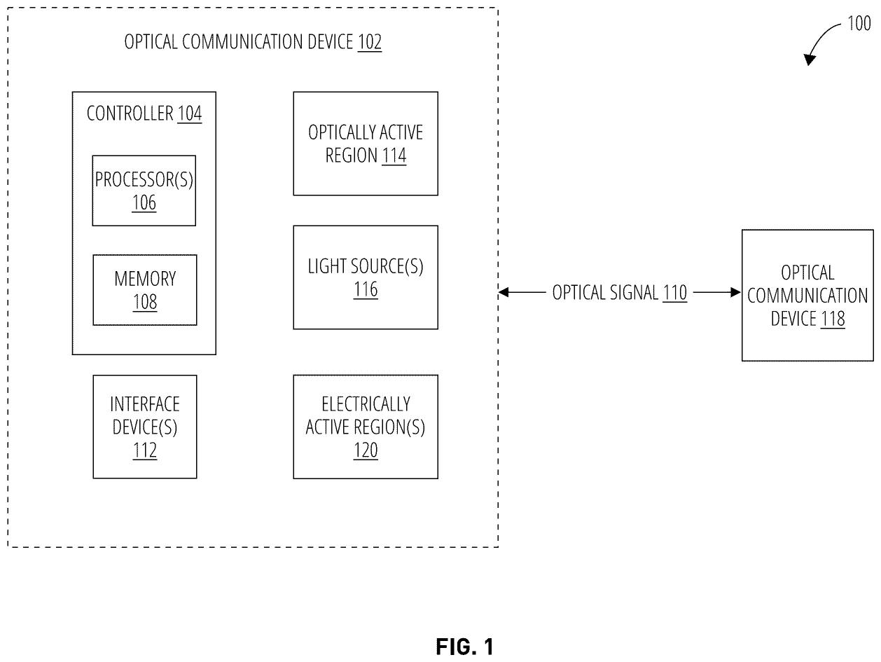

FIG. 1 is a functional block diagram illustrating a system 100 for optical communication between optical communication device 102 and optical communication device 118 via optical signal 110, in accordance with various aspects of the present disclosure. More generally, in some embodiments, optical communication device 102 is configured to transmit information by using one or more electrically active regions 120 to modulate light from one or more light source(s) 116 into an optical signal 110 that is subsequently transmitted from optical communication device 102 to optical communication device 118 via an optical fiber, a light guide, a wave guide, or other photonic device. Optical communication device 118 receives the optical signal 110 and demodulates the received optical signal 110 to extract the transmitted information. In some embodiments, optical communication device 102 is configured to receive information by demodulating optical signal 110 transmitted by optical communication device 118 to recover transmitted information. In some embodiments, optical communication device 102 may be configured to both transmit (via one or more light source(s) 116) and receive (via one or more light sensors) information. In some embodiments, optical communication device 102 may be configured to perform one of transmitting or receiving information.

It is appreciated that in some embodiments optical communication device 102 and optical communication device 118 may be distinct and separate devices (e.g., an optical transceiver or transmitter communicatively coupled via one or more optical fibers to a separate optical transceiver or receiver). However, in other embodiments, optical communication device 102 and optical communication device 118 may be part of a singular component or device (e.g., a smartphone, a tablet, a computer, optical device, or the like). For example, optical communication device 102 and optical communication device 118 may both be constituent components on a monolithic integrated circuit that are coupled to one another via a waveguide that is embedded within the monolithic integrated circuit and is adapted to carry optical signal 110 between optical communication device 102 and optical communication device 118 or otherwise transmit the optical signal between one place and another.

In the illustrated embodiment, optical communication device 102 includes a controller 104, one or more interface device(s) 112 (e.g., fiber optic couplers, light guides, waveguides, and the like), an optically active region 114, one or more electrically active regions 120, and one or more light source(s) 116 (e.g., light emitting diodes, lasers, and the like) coupled to one another. The controller 104 includes one or more processor(s) 106 (e.g., one or more central processing units, application specific circuits, field programmable gate arrays, or otherwise) and memory 108 (e.g., volatile memory such as DRAM and SAM, non-volatile memory such as ROM, flash memory, and the like). It is appreciated that optical communication device 118 may include the same or similar elements as optical communication device 102, which have been omitted for clarity. It is also appreciated that if the optical communication device 102 is configured to receive signals but not transmit signals, the light source(s) 116 may be omitted, while if the optical communication device 102 is configured to transmit signals but not receive signals, the light sensors may be omitted.

Controller 104 orchestrates operation of optical communication device 102 for transmitting and/or receiving optical signal 110. Controller 104 includes software (e.g., instructions included in memory 108 coupled to processor 106) and/or hardware logic (e.g., application specific integrated circuits, field-programmable gate arrays, and the like) that when executed by controller 104 causes controller 104 and/or optical communication device 102 to perform operations.

In some embodiments, controller 104 may choreograph operations of optical communication device 102 to cause light source(s) 116 to generate a signal that is transmitted via optically active region 114 and modulated by electrically active regions 120 into a modulated optical signal 110 that is subsequently transmitted to optical communication device 118 via interface device 112. In the same or another embodiment, controller 104 may choreograph operations of optical communication device 102 to cause a modulated signal to be received via optically active region 114 via interface device 112 from optical communication device 118, and detected by light sensors (not illustrated).

It is appreciated that in some embodiments certain elements of optical communication device 102 and/or optical communication device 118 may have been omitted to avoid obscuring certain aspects of the disclosure. For example, optical communication device 102 and optical communication device 118 may include amplification circuitry, lenses, or components to facilitate transmitting and receiving optical signal 110. It is further appreciated that in some embodiments optical communication device 102 and/or optical communication device 118 may not necessarily include all elements illustrated in FIG. 1.

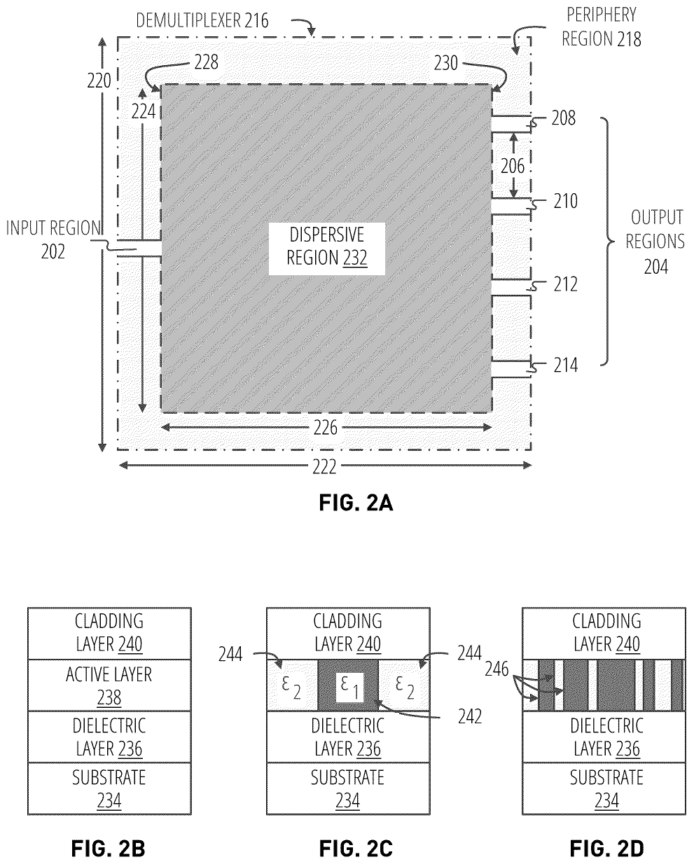

FIG. 2A-FIG. 2D illustrate different views of an example photonic demultiplexer, in accordance with an embodiment of the present disclosure. Photonic demultiplexer 216 is one possible implementation of functionality provided by optically active region 114 illustrated in FIG. 1, though it should be noted that other functionality may be implemented by the optically active region 114, including but not limited to beam splitting/joining without separating wavelengths, or simple point-to-point waveguide transmission. It is further appreciated that while discussion henceforth may be directed towards photonic integrated circuits capable of demultiplexing a plurality of distinct wavelength channels from a multi-channel optical signal, that in other embodiments, a demultiplexer (e.g., demultiplexer 216) may also or alternatively be capable of multiplexing a plurality of distinct wavelength channels into a multi-channel optical signal or performing other manipulation of incoming optical signals. The demultiplexer 216 is illustrated because it is an example that clearly shows the manipulation of the incoming optical signal toward a particular physical region of the physical device, and such functionality would be similarly useful for guiding and manipulating phase of the optical signal to match phase with an RF waveguide in a modulator device as described in further detail below.

FIG. 2A illustrates a cross-sectional view of demultiplexer 216 along a lateral plane within an active layer defined by a width 220 and a length 222 of the demultiplexer 216. As illustrated, demultiplexer 216 includes an input region 202, a plurality of output regions 204, and a dispersive region optically disposed between the input region 202 and plurality of output regions 204. The input region 202 and plurality of output regions 204 (e.g., output region 208, output region 210, output region 212, and output region 214) may each be waveguides (e.g., slab waveguide, strip waveguide, slot waveguide, or the like) capable of propagating light along the path of the waveguide. The dispersive region 232 includes a first material and a second material (see, e.g., FIG. 2D) inhomogeneously interspersed to form a plurality of interfaces that each correspond to a change in refractive index of the dispersive region 232 and collectively structure the dispersive region 232 to optically separate each of a plurality of distinct wavelength channels (e.g., Ch. 1, Ch. 2, Ch. 3, . . . . Ch. N) from a multi-channel optical signal and respectively guide each of the plurality of distinct wavelength channels to a corresponding one of the plurality of output regions 204 when the input region 202 receives the multi-channel optical signal. In other words, input region 202 is adapted to receive the multi-channel optical signal including a plurality of distinct wavelength channels and the plurality of output regions 204 are adapted to each receive a corresponding one of the plurality of distinct wavelength channels demultiplexed from the multi-channel optical signal via dispersive region 232.

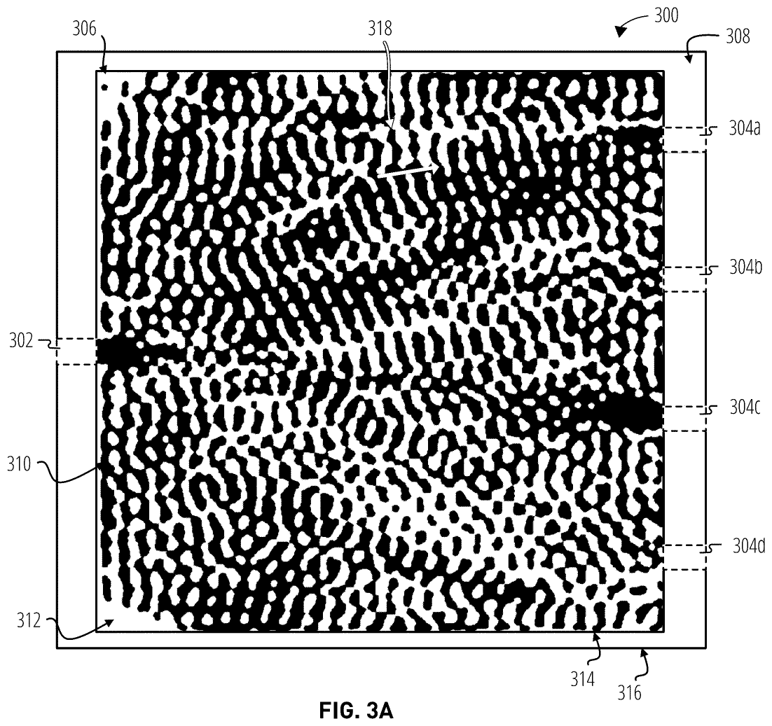

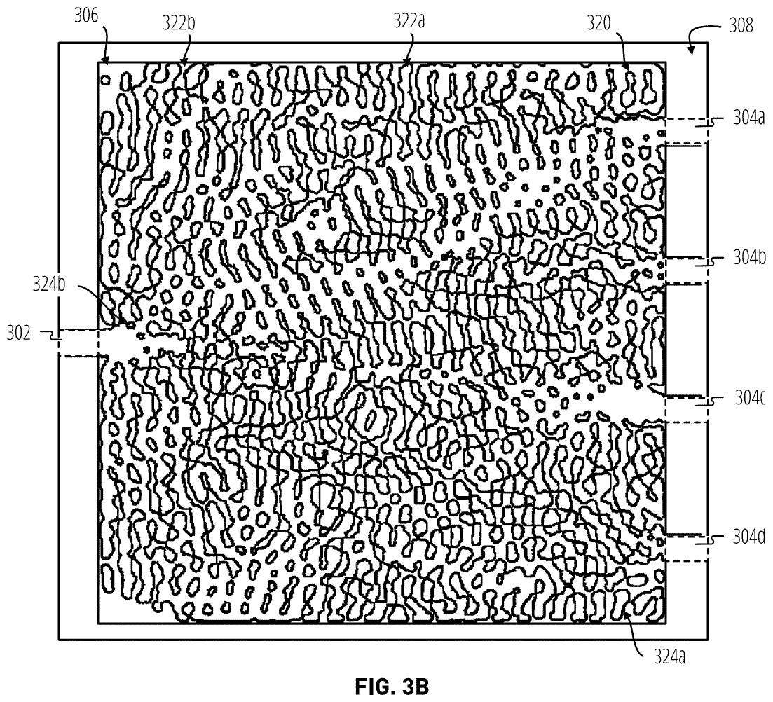

As illustrated in FIG. 2A, and more clearly shown in FIG. 2D and FIG. 3A-FIG. 3B, the shape and arrangement of the first and second material that are inhomogeneously interspersed create a plurality of interfaces that collectively form a material interface pattern along a cross-sectional area of dispersive region 232 that is at least partially surrounded by a periphery region 218 that includes the second material. In some embodiments periphery region 218 has a substantially homogeneous composition that includes the second material. In the illustrated embodiment, dispersive region 232 includes a first side 228 and a second side 230 that each interface with an inner boundary (i.e., the unlabeled dashed line of periphery region 218 disposed between dispersive region 232 and dashed-dotted line corresponding to an outer boundary of periphery region 218). First side 228 and second side 230 are disposed correspond to opposing sides of dispersive region 232. Input region 202 is disposed proximate to first side 228 (e.g., one side of input region 202 abuts first side 228 of dispersive region 232) while each of the plurality of output regions 204 are disposed proximate to second side 230 (e.g., one side of each of the plurality of output regions 204 abuts second side 230 of dispersive region 232).

In the illustrated embodiment each of the plurality of output regions 204 are parallel to each other one of the plurality of output regions 204. However, in other embodiments the plurality of output regions 204 may not be parallel to one another or even disposed on the same side (e.g., one or more of the plurality of output regions 204 and/or input region 202 may be disposed proximate to sides of dispersive region 232 that are adjacent to first side 228 and/or second side 230). In some embodiments adjacent ones of the plurality of output regions are separated from each other by a common separation distance when the plurality of output regions includes at least three output regions. For example, as illustrated adjacent output region 208 and output region 210 are separated from one another by distance 206, which may be common to the separation distance between other pairs of adjacent output regions.

As illustrated in the embodiment of FIG. 2A, demultiplexer 216 includes four output regions 204 (e.g., output region 208, output region 210, output region 212, output region 214) that are each respectively mapped (i.e., by virtue of the structure of dispersive region 232) to a respective one of four channels included in a plurality of distinct wavelength channels. More specifically, the plurality of interfaces of dispersive region 232, defined by the inhomogeneous interspersion of a first material and a second material, form a material interface pattern along a cross-sectional area of the dispersive region 232 (e.g., as illustrated in FIG. 2A, FIG. 3A, or FIG. 3B) to cause the dispersive region 232 to optically separate each of the four channels from the multi-channel optical signal and route each of the four channels to a respective one of the four output regions 204 when the input region 202 regions the multi-channel optical signal.

It is noted that the first material and second material of dispersive region 232 are arranged and shaped within the dispersive region such that the material interface pattern is substantially proportional to a design obtainable with an inverse design process, which will be discussed in greater detail later in the present disclosure. More specifically, in some embodiments, the inverse design process may include iterative gradient-based optimization of a design based at least in part on a loss function that incorporates a performance loss (e.g., to enforce functionality) and a fabrication loss (e.g., to enforce fabricability and binarization of a first material and a second material) that is reduced or otherwise adjusted via iterative gradient-based optimization to generate the design. In the same or other embodiments, other optimization techniques may be used instead of, or jointly with, gradient-based optimization. Advantageously, this allows for optimization of a near unlimited number of design parameters to achieve functionality and performance within a predetermined area that may not have been possible with conventional design techniques.

FIG. 2B illustrates a vertical schematic or stack of various layers that are included in the illustrated embodiment of demultiplexer 216. However, it is appreciated that the illustrated embodiment is not exhaustive and that certain features or elements may be omitted to avoid obscuring certain aspects of the invention. It is further appreciated that the illustrated schematic or stack of various layers may be used in devices other than a demultiplexer.

In the illustrated embodiment, demultiplexer 216 includes substrate 234, dielectric layer 236, active layer 238 (e.g., as shown in the cross-sectional illustration of FIG. 2A), and a cladding layer 240. In some embodiments, demultiplexer 216 may be, in part or otherwise, a photonic integrated circuit or silicon photonic device that is compatible with conventional fabrication techniques (e.g., lithographic techniques such as photolithographic, electron-beam lithography and the like, sputtering, thermal evaporation, physical and chemical vapor deposition, and the like).

In one embodiment a silicon on insulator (SOI) wafer may be initially provided that includes a support substrate (e.g., a silicon substrate) that corresponds to substrate 234, a silicon dioxide dielectric layer that corresponds to dielectric layer 236, a silicon layer (e.g., intrinsic, doped, or otherwise), and a oxide layer (e.g., intrinsic, grown, or otherwise). In one embodiment, the silicon in the active layer 238 may be etched selectively by lithographically creating a pattern on the SOI wafer that is transferred to SOI wafer via a dry etch process (e.g., via a photoresist mask or other hard mask) to remove portions of the silicon. The silicon may be etched all the way down to dielectric layer 236 to form voids that may subsequently be backfilled with silicon dioxide that is subsequently encapsulated with silicon dioxide to form cladding layer 240. In one embodiment, there may be several etch depths including a full etch depth of the silicon to obtain the targeted structure. In one embodiment, the silicon may be 206 nm thick and thus the full etch depth may be 206 nm. In some embodiments, this may be a two-step encapsulation process in which two silicon dioxide depositions are performed with an intermediate chemical mechanical planarization used to yield a planar surface.

FIG. 2C illustrates a more detailed view of active layer 238 (relative to FIG. 2B) taken along a portion of periphery region 218 that includes input region 202 of FIG. 2A. In the illustrated embodiment, active layer 238 includes a first material 242 with a refractive index of &1 and a second material 244 with a refractive index of 82 that is different from &1. Homogenous regions of the first material 242 and the second material 244 may form waveguides or portions of waveguides that correspond to input region 202 and plurality of output regions 204 as illustrated in FIG. 2A and FIG. 2C. As discussed in further detail below, for modulator devices, the refractive indices (or other optical characteristics) of the first material 242 and the second material 244 may change based on the electrical performance of the electrically active region 120 of the physical device.

FIG. 2D illustrates a more detailed view of active layer 238 (relative to FIG. 2B) taken along dispersive region 232. As described previously, active layer 238 includes a first material 242 (e.g., silicon) and a second material 244 (e.g., silicon dioxide) that are inhomogeneously interspersed to form a plurality of interfaces 246 that collectively form a material interface pattern. Each of the plurality of interfaces 246 that form the interface pattern correspond to a change in refractive index of dispersive region 232 to structure the dispersive region (i.e., the shape and arrangement of first material 242 and second material 244) to provide, at least in part, the functionality of demultiplexer 216 (i.e., optical separation of the plurality of distinct wavelength channels from the multi-channel optical signal and respective guidance of each of the plurality of distinct wavelength channels to the corresponding one of the plurality of output regions 204 when the input region 202 receives the multi-channel optical signal).

It is appreciated that in the illustrated embodiments of demultiplexer 216 as shown in FIG. 2A-FIG. 2D, the change in refractive index is shown as being vertically consistent (i.e., the first material 242 and second material 244 form interfaces that are substantially vertical or perpendicular to a lateral plane or cross-section of demultiplexer 216. However, in the same or other embodiments, the plurality of interfaces (e.g., interfaces 246 illustrated in FIG. 2D) may not be substantially perpendicular with the lateral plane or cross-section of demultiplexer 216.

FIG. 3A illustrates a more detailed cross-sectional view of a dispersive region of example photonic demultiplexer 300, in accordance with an embodiment of the present disclosure. FIG. 3B illustrates a more detailed view of an interface pattern formed by the shape and arrangement of a first material 310 and a second material 312 for the dispersive region of the photonic demultiplexer 300 of FIG. 3A. Photonic demultiplexer 300 is one possible implementation of optically active region 114 illustrated in FIG. 1 and demultiplexer 216 illustrated in FIG. 2A-FIG. 2D. One of skill in the art will recognize that the manipulation of incoming optical signals provided by the illustrated dispersive region into separate locations based on wavelength is an example of a manipulation that can be achieved through inverse design of the optically active region 114, and in other embodiments, inverse design can be used to design the optically active region 114 to perform other manipulations, including but not limited to adjusting a phase shift in a device configured to operate as a modulator as described in further detail below.

As illustrated in FIG. 3A and FIG. 3B, photonic demultiplexer 300 includes an input region 302, a plurality of output regions 304a-304d, and a dispersive region 306 optically disposed between input region 302 and plurality of output regions 304a-304d. Dispersive region 306 is surrounded, at least in part, by a peripheral region 308 that includes an inner boundary 314 and an outer boundary 316. It is appreciated that like named or labeled elements of photonic demultiplexer 300 may similarly correspond to like named or labeled elements of other demultiplexers described in embodiments of the present disclosure.

The first material 310 (i.e., black colored regions within dispersive region 306) and second material 312 (i.e., white colored regions within dispersive region 306) of photonic demultiplexer 300 are inhomogeneously interspersed to create a plurality of interfaces that collectively form material interface pattern 320 as illustrated in FIG. 3B. More specifically, an inverse design process that utilizes iterative gradient-based optimization, Markov Chain Monte Carlo optimization, or other optimization techniques combined with first principles simulations to generate a design that is substantially replicated by dispersive region 306 within a proportional or scaled manner such that photonic demultiplexer 300 provides the desired functionality. In the illustrated embodiment, dispersive region 306 is structured to optically separate each of a plurality of distinct wavelength channels from a multi-channel optical signal and respectively guide each of the plurality of distinct wavelength channels to a corresponding one of the plurality of output regions 304a-304d when the input region 302 receives the multi-channel optical signal.

As illustrated in FIG. 3B, material interface pattern 320, which is defined by the black lines within dispersive region 306 and corresponds to a change in refractive index within dispersive region 306, includes a plurality of protrusions 322a-322b. A first protrusion 322a is formed of the first material 310 and extends from peripheral region 308 into dispersive region 306. Similarly, a second protrusion 322b is formed of the second material 312 and extends from peripheral region 308 into dispersive region 306. Further illustrated in FIG. 3B, dispersive region 306 includes a plurality of islands 324a-324b formed of either the first material 310 or the second material 312. The plurality of islands 324a-324b include a first island 324a that is formed of the first material 310 and is surrounded by the second material 312. The plurality of islands 324a-324b also includes a second island 324b that is formed of the second material 312 and is surrounded by the first material 310.

In some embodiments, material interface pattern 320 includes one or more dendritic shapes, wherein each of the one or more dendritic shapes are defined as a branched structure formed from first material 310 or second material 312 and having a width that alternates between increasing and decreasing in size along a corresponding direction. Referring back to FIG. 3A, for clarity, dendritic structure 318 is labeled with a white arrow having a black border. As can be seen, the width of dendritic structure 318 alternatively increases and decreases in size along a corresponding direction (i.e., the white labeled arrow overlaying a length of dendritic structure 318) to create a branched structure. It is appreciated that in other embodiments there may be no protrusions, there may be no islands, there may be no dendritic structures, or there may be any number, including zero, of protrusions, islands of any material included in the dispersive region 306, dendritic structures, or a combination thereof.

In some embodiments, the inverse design process includes a fabrication loss that enforces a minimum feature size, for example, to ensure fabricability of the design. In the illustrated embodiment of photonic demultiplexer 300 illustrated in FIG. 3A and FIG. 3B, material interface pattern 320 is shaped to enforce a minimum feature size within dispersive region 306 such that the plurality of interfaces within the cross-sectional area formed with first material 310 and second material 312 do not have a radius of curvature with a magnitude of less than a threshold size. For example, if the minimum feature size is 150 nm, the radius of curvature for any of the plurality of interfaces have a magnitude of less than the threshold size, which corresponds the inverse of half the minimum feature size (i.e., 1/75 nm⁻¹). Enforcement of such a minimum feature size prevents the inverse design process from generating designs that are not fabricable by considering manufacturing constraints, limitations, and/or yield. In the same or other embodiments, different or additional checks on metrics related to fabricability may be utilized to enforce a minimum width or spacing as a minimum feature size.

The multiplexer and demultiplexer illustrated and described above use the material interface pattern 320 within the optically active region 114 to manipulate the incident light to exhibit the desired dispersion behavior. Within the optically active region 114, the light may accumulate greater phase shift in some areas, and lesser phase shift in other areas. Though these effects are described above in the context of multiplexers and demultiplexers, similar effects may be detected and manipulated via inverse design within a point-to-point waveguide without separating or combining different wavelengths by using different loss metrics. In some embodiments, manipulation of the phase shift behavior of the incident light may be used to create highly performant optoelectronic modulators, with inverse design of both the optically active region 114 and the electrically active region 120 being available to further improve performance.

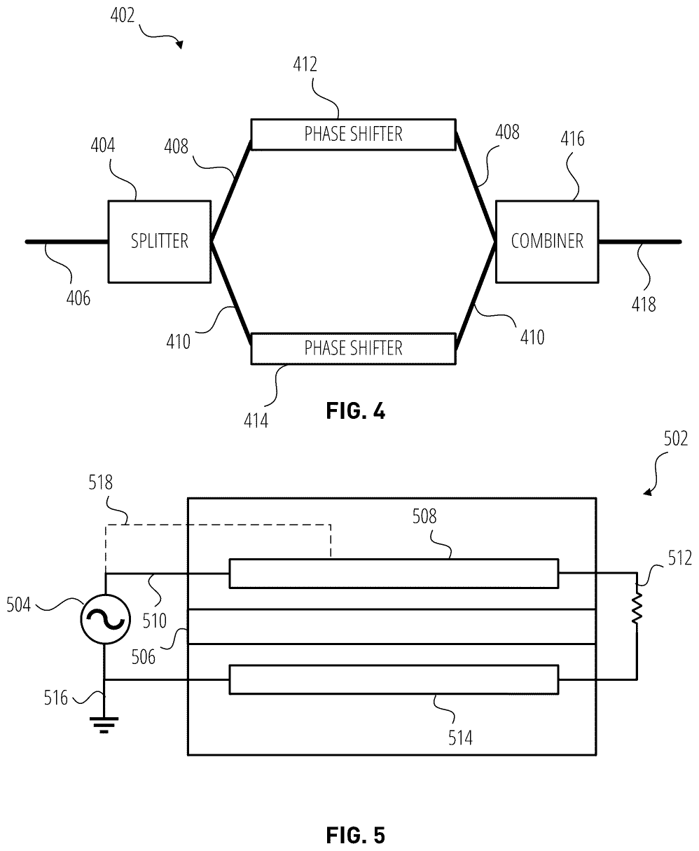

As discussed with respect to FIG. 1, an optical communication device that transmits information via the optical signal 110 modulates the outgoing optical signal 110 to represent an outgoing data signal. FIG. 4 illustrates a non-limiting example of a modulator device used in embodiments of the present disclosure. The illustrated modulator device 402 is an a Mach-Zehnder modulator, which is known to one of skill in the art to be usable to apply amplitude modulation to optical signals. In the modulator device 402, an optical carrier signal enters using an input waveguide 406 and is provided to a beam splitter 404. The beam splitter 404 splits the optical carrier signal to a first split waveguide 408 and a second split waveguide 410.

The first split waveguide 408 passes through a first phase shifter 412 and then to a beam combiner 416. The second split waveguide 410 may pass through a second phase shifter 414, or may pass straight through to the beam combiner 416. The first phase shifter 412 (and, optionally, the second phase shifter 414) change the phase of the optical signals in the first split waveguide 408 (and, optionally, the second split waveguide 410) according to an incoming data signal so that they constructively or destructively interfere, thus modulating the amplitude of the optical signal in the output waveguide 418.

A Mach-Zehnder interferometer is illustrated as the example of a modulator device due to its relative simplicity, which allows the novel features of the present disclosure to be discussed without being obscured. One will recognize that the techniques described herein can be used to design amplitude modulator devices of different architectures, and to design devices that modulate other aspects of the optical signal 110, including but not limited to frequency, polarization, or phase, without departing from the scope of the present disclosure.

Typically, to implement a phase shifter such as first phase shifter 412, electronic components are placed in relation to the waveguide such that an electrical signal applied to the electrical components affects optical characteristics of the waveguide. In this way, the phase of the optical signal transiting the waveguide may be adjusted. For example, some materials that may be used within the active layer 238, including but not limited to lithium niobate instead of (or in addition to) the silicon-based materials discussed above, may have a refractive index that changes based on a strength of the local electric field. FIG. 5 is a top-down view of one non-limiting example of a phase shifter that uses the electrical field generated by a transmission line proximate to a waveguide to adjust the phase of an optical signal in the waveguide. In the transmission line phase shifter 502, a first transmission line 508 and a second transmission line 514 are positioned proximate to a waveguide 506. A feed line 510 provides a signal from an electrical signal source 504 to a first end of the first transmission line 508. A second end of the first transmission line 508 is coupled to a load resistor 512 that prevents reflections of the signal, which is in turn coupled to a second transmission line 514 that completes the circuit via ground 516. In some embodiments, more than one feed line, such as additional feed line 518, may be present to provide the electrical signal to the first transmission line 508 in multiple physical locations.

Another type of phase shifter is a carrier depletion modulator. In a carrier depletion modulator, a p-n diode is formed at least partially inside the waveguide by applying doping to the active layer 238. By using the electrical signal to apply a reverse bias to the p-n diode, the depletion of carriers in the diode affects the optical characteristics of the waveguide in accordance with the signal.

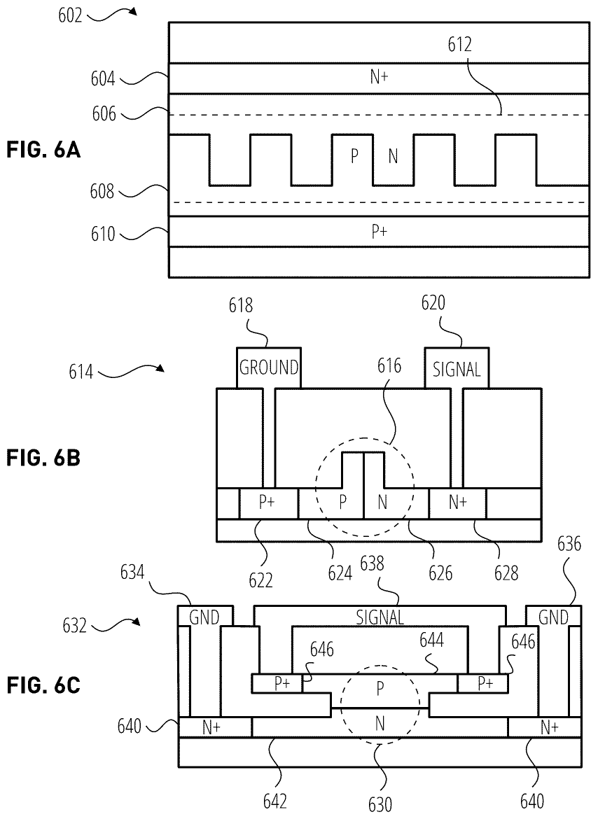

A wide variety of doping patterns may be used to create the p-n diode in association with the waveguide. FIG. 6A is a top-down view of a non-limiting example of a carrier depletion modulator device that uses an interdigitated pattern. In the interdigitated phase shifter 602, a first doped region 606 (such as an n-doped region) and a second doped region 608 (such as a p-doped region) are formed with an interdigitated pattern separating the first doped region 606 and the second doped region 608 and forming the p-n junction. The waveguide 612 is illustrated in dashed line, and overlaps with the first doped region 606 and second doped region 608. The first doped region 606 may be in contact with a first highly doped region 604 that provides a coupling to one or more electrodes, and the second doped region 608 may be in contact with a second highly doped region 610 that provides a coupling to one or more electrodes, such that a circuit is formed between the doped regions and the electrical signal source (not shown).

FIG. 6B is a cross-sectional view of a non-limiting example of a carrier depletion modulator device that uses a horizontally arranged diode. In the horizontally arranged phase shifter 614, a first doped region 624 (such as a p-doped region) is arranged horizontally next to a second doped region 626 (such as an n-doped region), such that the p-n junction is arranged in a vertical plane. The waveguide 616, illustrated in dashed line, includes the p-n junction. The first doped region 624 may be in contact with a first highly doped region 622 that provides a coupling to a first electrode 618, while the second doped region 626 may be in contact with a second highly doped region 628 that provides a coupling to a second electrode 620. The first electrode 618 and second electrode 620 may be in a circuit with the electrical signal source (not shown).

FIG. 6C is a cross-sectional view of a non-limiting example of a carrier depletion modulator device that uses a vertically arranged diode. In the vertically arranged phase shifter 632, a first doped region 642 (such as an n-doped region) is arranged vertically under a second doped region 644 (such as a p-doped region), such that the p-n junction is arranged in a horizontal plane. The waveguide 630, illustrated in dashed line, includes at least a portion of the p-n junction. The first doped region 642 may be in contact with a first highly doped region 640 (in multiple non-contiguous locations) that provides a coupling to a first electrode 634 and a second electrode 636, while the second doped region 644 may be in contact with a second highly doped region 646 (in multiple non-contiguous locations) that provides a coupling to third electrode 638. The first electrode 634, second electrode 636, and third electrode 638 may be in a circuit with the electrical signal source (not shown).

One will recognize that the transmission line phase shifter 502, interdigitated phase shifter 602, horizontally arranged phase shifter 614, and vertically arranged phase shifter 632 are illustrated herein as a sample of the variety of designs that may be used for a traveling wave modulator device, and should not be seen as limiting. In some embodiments, aspects of these designs may be combined, additional/other dopants may be used, or other adjustments may be made as discussed in further detail below.

In designing an optical modulator (e.g., a traveling wave modulator such as the modulator devices illustrated and discussed above, or other devices wherein the input is a radio frequency (RF) signal and the output is the modulated optical signal 110), a temporal characteristic of an electrically active region 120 (e.g., a depletion region minority carrier transit time, charge distribution behavior, or other temporal characteristic of the electrical components) may limit the performance of the system. Accordingly, care must be taken to ensure that the properties of the optically active regions 114 and the electrically active regions 120 are well matched. For example, as the optical signal from the light source 116 propagates down the length of a carrier depletion modulator device, the optical signal experiences some amount of phase shift as it propagates down the waveguide. The rate of propagation down the waveguide should match the location of the change in the charge distribution such that further phase shift adds constructively to a currently obtained phase shift as the wave propagates through the waveguide, such that the end result is a well-modulated-in-time optical signal. The electrically active regions 120 and the circuitry that provides the RF signal thereto to induce the change in the charge distribution should also be designed carefully, possibly by providing different delays in the driving voltage versus position down the waveguide, by providing different shapes to the electrically active regions 120, or by adjusting other parameters.

Traditional design techniques treat the waveguide as a two-dimensional cross section with some finite amount of phase accumulation per length. However, simply changing the length of the waveguide in order to adjust the amount of phase accumulation does not provide a large amount of adjustability, and so does not allow for the design of highly performant devices as would be possible if more adjustments were possible during the design process. What is desired are advanced techniques that explore a greater percentage of the potential design space in such a way that provides an optimum amount of phase accumulation in order to create very highly performant optical communication devices 102.

The present disclosure provides techniques wherein the design of both the optically active region 114 and the electrically active region 120 may take on other topologies via inverse design and/or shape optimization in order to improve the coupling between the optical and RF propagation. The present techniques provide more complicated analysis than previous techniques, and avoid limitations of designs that are analyzed as a two-dimensional cross section with a uniform accumulation of phase shift per unit length. The optimization may take into account the RF input waveform, a desired optical modulated output waveform, structural parameters of the optically active region 114 and the electrically active region 120, and may also include additional components such as pulse shaping networks and signal routing to further improve the performance of the resulting device.

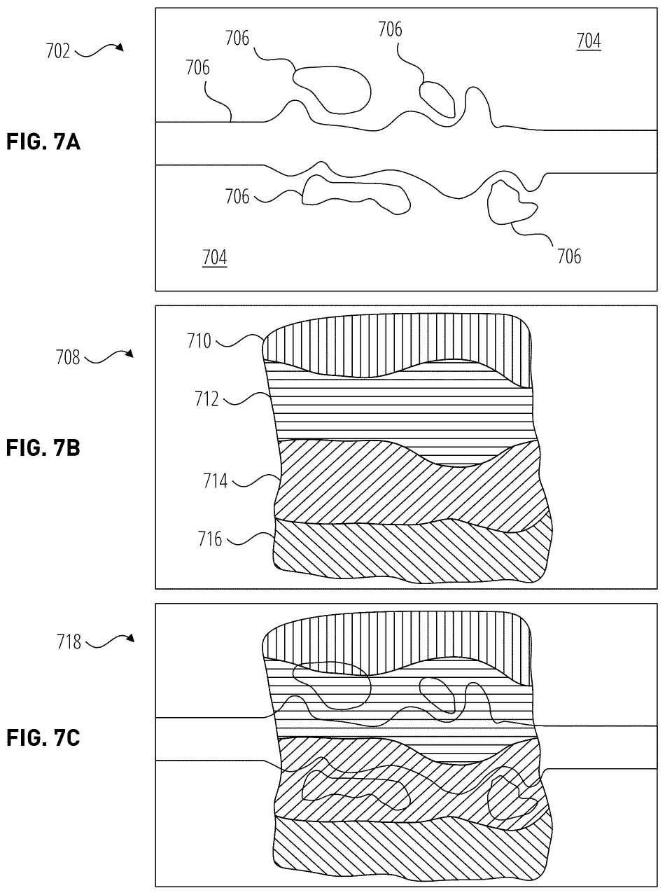

FIG. 7A-FIG. 7C are schematic illustrations of a non-limiting example embodiment of a design of an optically active region and an electrically active region of a modulator device obtained via inverse design and/or shape optimization according to various aspects of the present disclosure. Each of the illustrations in FIG. 7A-FIG. 7C are a top view of a portion of the design region of the modulator device.

In FIG. 7A, an optically active region design 702 is shown. Similar to the design of the photonic demultiplexer 300 illustrated in FIG. 3A-FIG. 3B, the optically active region design 702 includes regions of a first material 704 and a second material 706, wherein an interface pattern between the first material 704 and second material 706 affects the propagation of an optical signal received at an input port of the modulator device. As described elsewhere herein, the patterns of the first material 704 and the second material 706 may be obtained via an inverse design process that optimizes the propagation of the optical signal through the optically active region in coordination with the behavior of the electrically active region in order to maximize modulation performance.

In FIG. 7B, an electrically active region design 708 is shown. Similar to the designs in FIG. 6A-FIG. 6C, the electrically active region design 708 includes a first highly doped region 710, a first doped region 712, a second doped region 714, and a second highly doped region 716. Each of these regions has a shape that may be obtained via an inverse design process that, in coordination with the design of the optically active region, maximizes modulation performance.

FIG. 7C illustrates a combined modulator design 718, with the optically active region design 702 and the electrically active region design 708 superimposed on each other. This combined design, in which designs for both the optically active region and the electrically active region of the modulator device are optimized using inverse design techniques, can provide increased modulation performance versus traditional modulator designs, and also versus designs in which only one of the electrically active region or the optically active region is obtained via inverse design.

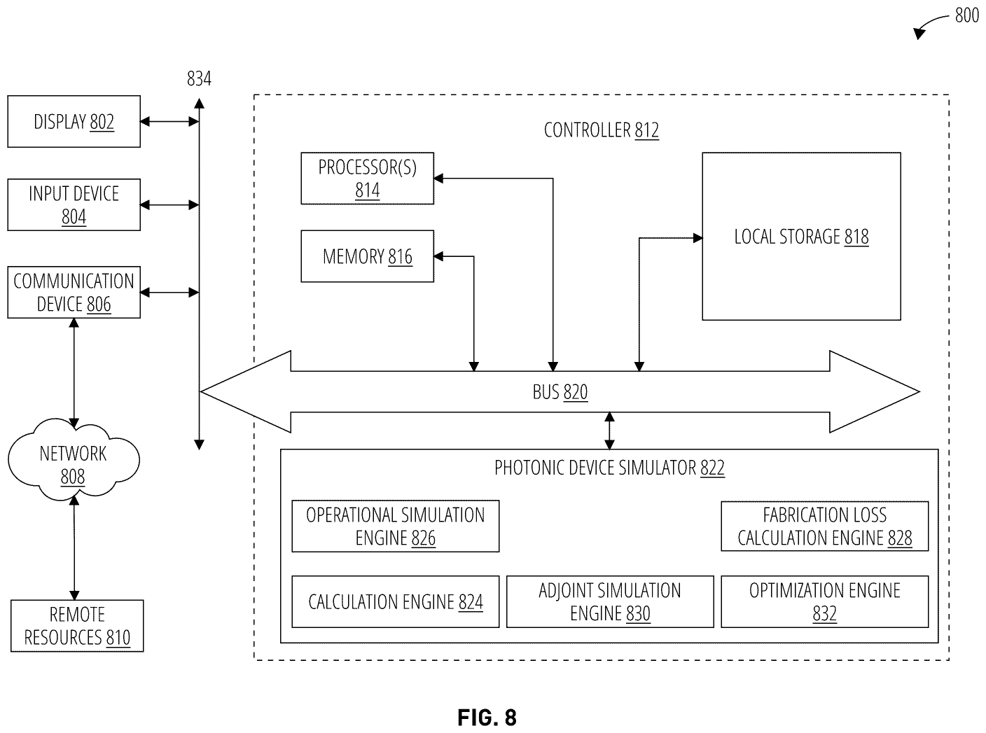

FIG. 8 is a functional block diagram illustrating a computing system 800 for generating a design of a photonic integrated circuit (i.e., photonic device), in accordance with an embodiment of the disclosure. Computing system 800 may be utilized to perform an inverse design process that generates a design using iterative gradient-based optimization that takes into consideration the underlying physics that govern the operation of the photonic integrated circuit and the related circuitry. More specifically, computing system 800 is a design tool that may be utilized to optimize structural parameters (e.g., shape and arrangement of a first material and a second material within the optically active region 114 of the embodiments described in the present disclosure, as well as shape and location of p-n junctions, feed lines, and/or other structures within or associated with the electrically active regions 120 of the embodiments described in the present disclosure) of photonic integrated circuits based on first-principles simulations (e.g., electromagnetic simulations to determine responses to electrical signals and optical field responses of the photonic device to optical signals) and iterative gradient-based optimization. In other words, computing system 800 may provide a design obtained via the inverse design process that can be used to fabricate an optical communication device 102 as illustrated in FIG. 1. An optically active region of the optical communication device 102 may include structures having a pattern with features similar to those illustrated in FIG. 4, while one or more electrically active regions—which may overlap the optically active region—may also include similar arbitrary shapes as the result of using the inverse design process to adjust the design.

As illustrated, computing system 800 includes controller 812, display 802, input device(s) 804, communication device(s) 806, network 808, remote resources 810, bus 834, and bus 820. Controller 812 includes processor 814, memory 816, local storage 818, and photonic device simulator 822. Photonic device simulator 822 includes operational simulation engine 826, fabrication loss calculation engine 828, calculation engine 824, adjoint simulation engine 830, and optimization engine 832. As used herein, “engine” refers to logic embodied in hardware or software instructions, which can be written in one or more programming languages, including but not limited to C, C++, C#, COBOL, JAVA™, PHP, Perl, HTML, CSS, Javascript, VBScript, ASPX, Go, and Python. An engine may be compiled into executable programs or written in interpreted programming languages. Software engines may be callable from other engines or from themselves. Generally, the engines described herein refer to logical modules that can be merged with other engines, or can be divided into sub-engines. The engines can be implemented by logic stored in any type of computer-readable medium or computer storage device and be stored on and executed by one or more general purpose computers, thus creating a special purpose computer configured to provide the engine or the functionality thereof. The engines can be implemented by logic programmed into an application-specific integrated circuit (ASIC), a field-programmable gate array (FPGA), or another hardware device.

It is appreciated that in some embodiments, controller 812 may be a distributed system. It is also appreciated that in some embodiments, the computing system 800 may include fewer than all of the components illustrated in FIG. 8. For example, the computing system 800 may be implemented solely by one or more computing devices configured to perform the actions attributed to controller 812.

Controller 812 is coupled to display 802 (e.g., a light emitting diode display, a liquid crystal display, and the like) coupled to bus 834 through bus 820 for displaying information to a user utilizing computing system 800 to optimize structural parameters of the photonic device (e.g., a modulator device). Input device 804 is coupled to bus 834 through bus 820 for communicating information and command selections to processor 814. Input device 804 may include a mouse, trackball, keyboard, stylus, or other computer peripheral, to facilitate an interaction between the user and controller 812. In response, controller 812 may provide verification of the interaction through display 802.

Another device, which may optionally be coupled to controller 812, is a communication device 806 for accessing remote resources 810 of a distributed system via network 808. Communication device 806 may include any of a number of networking peripheral devices such as those used for coupling to an Ethernet, Internet, or wide area network, and the like. Communication device 806 may further include a mechanism that provides connectivity between controller 812 and the outside world. Note that any or all of the components of computing system 800 illustrated in FIG. 8 and associated hardware may be used in various embodiments of the present disclosure. The remote resources 810 may be part of a distributed system and include any number of processors, memory, and other resources for optimizing the structural parameters of the photonic device.

Controller 812 orchestrates operation of computing system 800 for optimizing the design of the photonic device. Processor 814 (e.g., one or more central processing units, graphics processing units, and/or tensor processing units, etc.), memory 816 (e.g., volatile memory such as DRAM and SRAM, non-volatile memory such as ROM, flash memory, and the like), local storage 818 (e.g., magnetic memory such as computer disk drives), and the photonic device simulator 822 are coupled to each other through bus 820. Controller 812 includes software (e.g., instructions included in memory 816 coupled to processor 814) and/or hardware logic (e.g., application specific integrated circuits, field-programmable gate arrays, and the like) that when executed by controller 812 causes controller 812 or computing system 800 to perform operations. The operations may be based on instructions stored within any one of, or a combination of, memory 816, local storage 818, photonic device simulator 822, and remote resources 810 accessed through network 808.

In the illustrated embodiment, the components of photonic device simulator 822 are utilized to optimize structural parameters and other configurable aspects of the photonic device (e.g., optically active region 114 and electrically active region 120 of FIG. 1). In some embodiments, computing system 800 may optimize the structural parameters of the photonic device via, inter alia, simulations (e.g., operational and adjoint simulations) that utilize a finite-difference time-domain (FDTD) method, a finite-difference frequency-domain (FDFD) method, or any other suitable technique to model the physical response (e.g., electric and magnetic fields within the photonic device, p-n junction behaviors such as depletion region region minority carrier transit, etc.) for the structural parameters, and other operational and adjoint simulations for the semiconductor behavior of the optically active region 114 and electrically active region 120.

The operational simulation engine 826 provides instructions for performing an electromagnetic simulation of the photonic device operating in response to an optical source (e.g., an excitation source) and an electrical source within a simulated environment. In particular, the operational simulation simulates electrical performance of the electrically active region in response to the electrical source in order to adjust optical characteristics within the optically active region, and then determines an optical field response using the adjusted optical characteristics in the simulated environment (and thus the photonic device, which is described by the simulated environment) in response to the optical source.

Fabrication loss calculation engine 828 provides instructions for determining a fabrication loss, which is utilized to enforce various constraints on the designs created for the electrically active region and the optically active region to ensure fabricability. For example, in some embodiments, the fabrication loss is used to enforce binarization of the design (e.g., such that the active layer 238 of the photonic device includes a first material and a second material that are interspersed to form a plurality of interfaces, as opposed to any intermediate values; that at most one type of dopant is applied to each voxel of the design; etc.). As another example, in some embodiments, the fabrication loss may be used to enforce contiguity of doped regions within the electrically active regions (e.g., no islands of a first doped material within a second doped material without having an electrode attached, etc.). Calculation engine 824 computes a loss metric determined via a loss function that incorporates a performance loss, based on the performance metric, and may also incorporate the fabrication loss. Adjoint simulation engine 830 is utilized in conjunction with the operational simulation engine 826 to perform an adjoint simulation of the photonic device to backpropagate the loss metric through the simulated environment via the loss function to determine how changes in the structural parameters of the photonic device influence the loss metric. Optimization engine 832 is utilized to update the structural parameters of the photonic device and the circuit parameters to reduce the loss metric and generate a revised description (i.e., revising the design) of the photonic device.

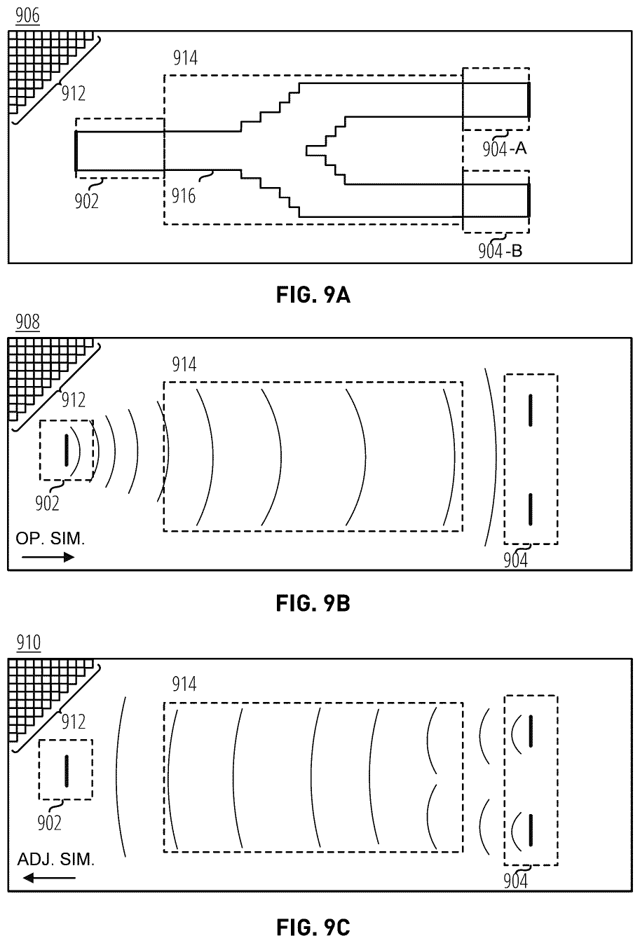

FIG. 9A-FIG. 9C respectively illustrate non-limiting example embodiments of an initial set up of a simulated environment 906 describing a photonic device, performing an operational simulation of the photonic device in response to an optical source and an electrical source within the simulated environment 908, and performing an adjoint simulation of the photonic device within the simulated environment 910 according to various aspects of the present disclosure. The initial set up of the simulated environment, 1-dimensional representation of the simulated environment, operational simulation of the physical device, and adjoint simulation of the physical device may be implemented with computing system 800 illustrated in FIG. 8.

As illustrated in FIG. 9A-FIG. 9C, simulated environment is represented in two dimensions. However, it is appreciated that other dimensionality (e.g., 3-dimensional space) may also be used to describe simulated environment and the photonic device. In some embodiments, optimization of structural parameters of the photonic device illustrated in FIG. 9A-FIG. 9C may be achieved via an inverse design process including, inter alia, simulations (e.g., operational simulations and adjoint simulations) that utilize a finite-difference time-domain (FDTD) method, a finite-difference frequency-domain (FDFD) method, or any other suitable technique to model the field response (e.g., electric and magnetic field) to an optical source.

FIG. 9A illustrates a demonstrative simulated environment 906 describing a photonic integrated circuit in accordance with a non-limiting example embodiment of the present disclosure. The illustrated photonic integrated circuit may be a modulator device such as modulator device 402, or one or more components thereof, such as a waveguide, a beam splitter, a phase shifter, etc. More specifically, in response to receiving an initial description of a photonic device defined by one or more structural parameters (e.g., an input design), a system (e.g., computing system 800 of FIG. 8) configures a simulated environment 906 to be representative of the photonic device.

As illustrated, the simulated environment 906 (and subsequently the photonic device) is described by a plurality of voxels 912, which represent individual elements (i.e., discretized) of the two-dimensional (or other dimensionality) space. Each of the voxels 912 is illustrated as a two-dimensional square; however, it is appreciated that the voxels may be represented as cubes or other shapes in three-dimensional space. It is appreciated that the specific shape and dimensionality of the plurality of voxels 912 may be adjusted dependent on the simulated environment 906 and photonic device being simulated. It is further noted that only a portion of the plurality of voxels 912 are illustrated to avoid obscuring other aspects of the simulated environment 906.

Each of the plurality of voxels 912 may be associated with one or more structural values and one or more simulated performance values (e.g., a field value, a source value, etc.). Collectively, the structural values of the simulated environment 906 describe the structural parameters of the photonic device, and may include optical structural parameters relating to the material interface pattern 320 formed in the active layer 238, and electrical structural parameters relating to dopants in the design region and/or other electrically active elements of the physical device. In one embodiment, the optical structural parameters may include values that correspond to a relative permittivity, permeability, and/or refractive index that collectively describe structural (i.e., material) boundaries or interfaces of the photonic device. For example, an interface 916 is representative of where relative permittivity changes within the simulated environment 906 and may define a boundary of the photonic device where a first material meets or otherwise interfaces with a second material to form a waveguide. The field value describes the field (or loss) response that is calculated (e.g., via Maxwell's equations) in response to an optical source described by the source value. The field response, for example, may correspond to a vector describing the electric and/or magnetic fields (e.g., in one or more orthogonal directions) at a particular time step for each of the plurality of voxels 912. Thus, the field response may be based, at least in part, on the structural parameters of the photonic device and the optical source.

In the illustrated embodiment, the photonic device has a design region 914 (e.g., corresponding to dispersive region 232 of FIG. 2A, and/or dispersive region 306 of FIG. 3A of a demultiplexer), in which structural parameters of the physical device may be updated or otherwise revised. While a demultiplexer is described as a non-limiting example, the illustrated photonic device may be a beam splitter, a phase shifter, a modulator, or any other type of optoelectronic device. Through an inverse design process, iterative gradient-based optimization of a loss metric determined from a loss function is performed to generate a design of the photonic device that functionally causes an input optical signal to be processed and guided from input port 902 to the output ports 904. Careful selection of the loss metric allows the photonic device to be optimized to perform various functions. For example, for a demultiplexer, the loss metric may measure whether input optical signals of a first wavelength band are output by the output port 904-A, while input optical signals of a second wavelength band are output by the output port 904-B. As another example, for a beam splitter, the loss metric may measure whether the output signals at the output port 904-A match the output signals at the output port 904-B. As yet another example, for a modulator, the loss metric may compare a phase of an output signal at the output port 904-A to a phase of an output signal at the output port 904-B.

Thus, input port 902 (e.g., corresponding to input region 202 of FIG. 2A, input region 302 of FIG. 3A, input waveguide 406 of FIG. 4, etc.) of the photonic device corresponds to a location of an optical source to provide an output (e.g., a Gaussian pulse, a wave, a waveguide mode response, and the like). The output of the optical source interacts with the photonic device based on the structural parameters (e.g., an electromagnetic wave corresponding to the optical source may be perturbed, retransmitted, attenuated, refracted, reflected, diffracted, scattered, absorbed, dispersed, amplified, or otherwise as the wave propagates through the photonic device within simulated environment 906). In other words, the optical source may cause the field response of the photonic device to change, which is dependent on the underlying physics governing the physical domain and the structural parameters of the photonic device, which may be adjusted by signals from an electrical source. The optical source originates or is otherwise proximate to input port 902 and is positioned to propagate (or otherwise influence the field values of the plurality of voxels) through the design region 914 towards output ports 904 of the photonic device.

In the illustrated embodiment, the input port 902 and output ports 904 are positioned outside of the design region 914. In other words, in the illustrated embodiment, only a portion of the structural parameters of the photonic device is optimizable. However, in other embodiments, the entirety of the photonic device may be placed within the design region 914 such that the structural parameters may represent any portion or the entirety of the design of the photonic device. The electric and magnetic fields within the simulated environment 906 (and subsequently the photonic device) may change (e.g., represented by field values of the individual voxels that collectively correspond to the field response of the simulated environment) in response to the optical source.

Though FIG. 9A illustrates the simulated environment 906 as including just features of the optically active region 114, it will be appreciated that the simulated environment 906 also includes features of the electrically active region 120, which may also be specified using the voxels 912, as will be discussed in further detail below.

The initial description of the photonic device, including initial structural parameters, optical source, electrical source, performance parameters or metrics, and other parameters describing the photonic device, are received by the system (e.g., computing system 800 of FIG. 8) and used to configure the simulated environment 906 for performing a first-principles based simulation of the photonic device. These specific values and parameters may be defined directly by a user (e.g., of computing system 800 in FIG. 8), indirectly (e.g., via controller 812 culling pre-determined values stored in memory 816, local storage 818, or remote resources 810), or a combination thereof.

FIG. 9B illustrates a non-limiting example embodiment of an operational simulation of the photonic device in response to an optical source and an electrical source within simulated environment 908, in accordance with various aspects of the present disclosure. In the illustrated embodiment, the photonic device may be an optical demultiplexer structured to optically separate each of a plurality of distinct wavelength channels included in a multi-channel optical signal received at input port 902 and respectively guide each of the plurality of distinct wavelength channels to a corresponding one of the plurality of output ports 904; a beam splitter structured to optically split an optical signal received at input port 902 into identical signals at each of the plurality of output ports 904; a modulator device structured to modulate an optical signal received at input port 902 based on an electrical signal received via one or more feed lines (not shown), or another type of photonic device. The optical source originates at input port 902 having a specified spatial, phase, and/or temporal profile. The operational simulation occurs over a plurality of time steps, including the illustrated time step. When performing the operational simulation, changes to the field response (e.g., the field value) for each of the plurality of voxels 912 are incrementally updated in response to the optical source over the plurality of time steps. The changes in the field response at a particular time step are based, at least in part, on the structural parameters, the optical source, changes to the optical characteristics determined based on the simulated electrical performance, and the field response of the simulated environment 910 at the immediately prior time step included in the plurality of time steps. Similarly, in some embodiments the source value of the plurality of voxels 912 is updated (e.g., based on the spatial profile and/or temporal profile describing the optical source). It is appreciated that the operational simulation is incremental and that the field values (as well as the source values electrical performance values, and optical characteristics) of the simulated environment 910 are updated incrementally at each time step as time moves forward for each of the plurality of time steps during the operational simulation. It is further noted that in some embodiments, the update is an iterative process and that the update of each value is based, at least in part, on the previous update of the values.

FIG. 9C illustrates a non-limiting example embodiment of an adjoint simulation within simulated environment 910 by backpropagating a loss metric, in accordance with various aspects of the present disclosure. More specifically, the adjoint simulation illustrated in FIG. 9C is a time-backwards simulation in which a loss metric is treated as an optical source that interacts with the photonic device and causes a loss response. In other words, an adjoint (or virtual source) based on the loss metric is placed at the output region (e.g., output ports 904) or other location that corresponds to a location used when determining the performance metric. The adjoint source(s) is then treated as a physical stimuli or an optical source during the adjoint simulation. A loss response of the simulated environment 908 is computed for each of the plurality of time steps (e.g., backwards in time) in response to the adjoint source. The loss response collectively refers to loss values of the plurality of voxels 912 that are incrementally updated in response to the adjoint source over the plurality of time steps. The change in loss response based on the loss metric may correspond to a loss gradient, which is indicative of how changes in the field response of the physical device influence the loss metric. The loss gradient and the field gradient may be combined in the appropriate way to determine a structural gradient of the photonic device/simulated environment (e.g., how changes in the structural parameters of the photonic device within the simulated environment influence the loss metric). Once the structural gradient of a particular cycle (e.g., operational and adjoint simulation) is known, the structural parameters may be updated to reduce the loss metric and generate a revised description or design of the optical structural parameters and electrical structural parameters of the photonic device.

In some embodiments, iterative cycles of performing the operational simulation, and adjoint simulation, determining the structural gradient, and updating the structural parameters to reduce the loss metric are performed successively as part of an inverse design process that utilizes iterative gradient-based optimization. An optimization scheme such as gradient descent may be utilized to determine specific amounts or degrees of changes to the structural parameters of the photonic device to incrementally reduce the loss metric. More specifically, after each cycle the structural parameters are updated (e.g., optimized) to reduce the loss metric. The operational simulation, adjoint simulation, and updating the structural parameters are iteratively repeated until the loss metric substantially converges, is otherwise below or within a threshold value or range, or a predetermined number of iterations have been performed.

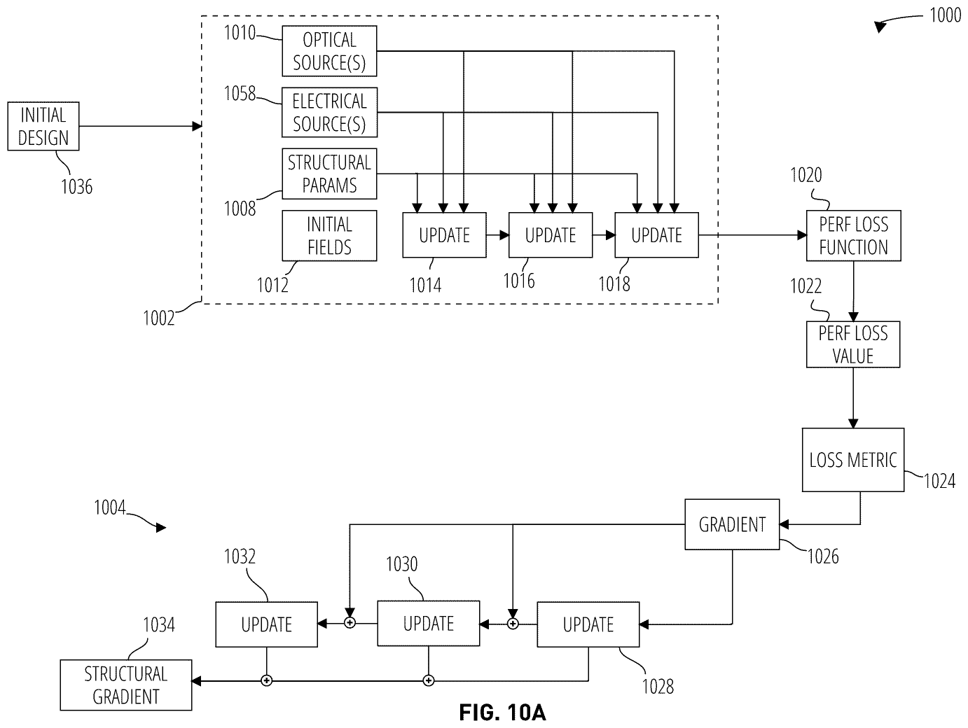

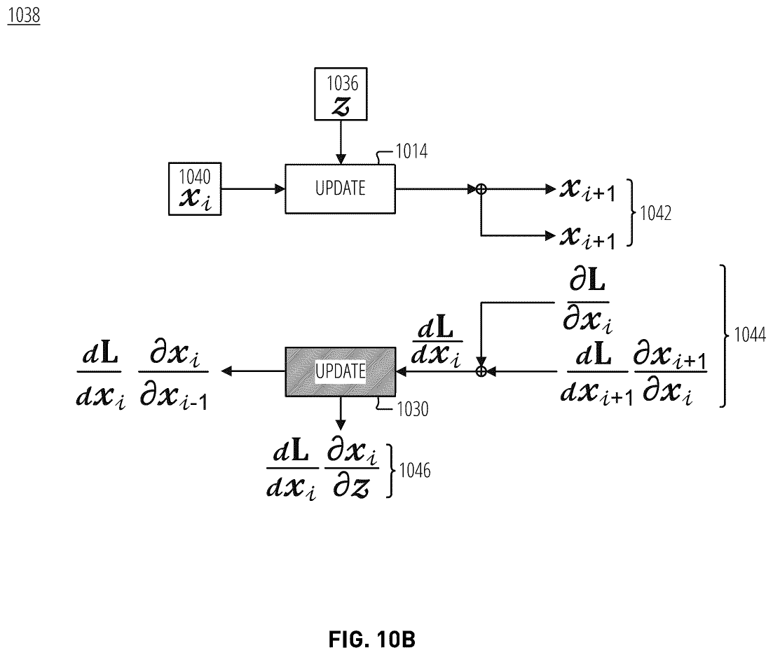

FIG. 10A is a flow chart 1000 illustrating example time steps for an operational simulation 1002 and an adjoint simulation 1004, in accordance with various aspects of the present disclosure. Flow chart 1000 is one possible implementation that a system may use to perform the operational simulation 1002 and adjoint simulation 1004 of the simulated environment describing a photonic integrated circuit and related circuitry (e.g., an optoelectronic modulator) illustrated above. In the illustrated embodiment, the operational simulation 1002 utilizes a finite-difference time-domain (FDTD) method to model the electrical performance and field response (both electric and magnetic) or loss response at each of a plurality of voxels for a plurality of time steps in response to physical stimuli corresponding to an optical source, electrical source, and/or adjoint source.

An initial design 1036 is determined that includes structural parameters for a physical device such as a photonic device to be simulated. In some embodiments, the initial design 1036 may include a plurality of geometric shape primitives, voxel patterns, or other parameters that define the structural parameters for the optically active region 114 and the electrically active region 120. In some embodiments, in addition to structural parameters for the optically active region 114 and the electrically active region 120 that lie within a design region 914, the structural parameters may include configuration parameters of other components. For example, the structural parameters may include a size, shape, or location of one or more feed lines that provide the electrical signal from the electrical source to the electrically active region 120. As another example, the structural parameters may include a location, design, or other configuration of one or more pulse shaping networks between the electrical source and the electrically active region 120.

In some embodiments, the structural parameters may be initialized to default or random values in order to avoid biasing the eventual outcome of the design process. In some embodiments, the initial design 1036 may be based on a design specification that includes performance goals for the physical device, design constraints for the physical device (e.g., a size and/or shape of the design region 914, a location of one or more input ports 902, a location of one or more output ports 904, a type of electrical source and/or signal to be provided, etc.), starting settings for various aspects of the structural parameters (e.g., an initial number of geometric shape primitives to specify features within the design region 914, an initial number of contact points and/or doped regions, etc.), initial structural parameters to be used, and/or any other relevant aspect of the design and/or optimization to be performed for the physical device.

After determining the initial design 1036, the operational simulation 1002 provides structural parameters 1008 from the initial design 1036 for the operational simulation of the optically active region 114 and the electrically active region 120. The operational simulation 1002 occurs over a plurality of time-steps (e.g., from an initial time step to a final time step over a pre-determined or conditional number of time steps having a specified time step size) and models changes (e.g., from the initial field values 1012) in electric and magnetic fields of a plurality of voxels describing the simulated environment and/or photonic device that collectively correspond to the field response.

More specifically, update operations (e.g., update operation 1014, update operation 1016, and update operation 1018) are iterative and based on the field response, structural parameters 1008, one or more optical sources 1010, and one or more electrical sources 1058. For example, for a given update operation, the electrical performance at each of the voxels 912 may be simulated based on the electrical structural parameters for the voxels 912 and an electrical signal from the electrical source 1058 during a time step.

The simulated electrical performance (e.g., state of carrier depletion, voltage, electrical field, etc.) is used to adjust optical characteristics of voxels 912 specified by the optical structural parameters for the time step. Optical performance at each of the voxels 912 (e.g., field values) are determined based on the signals from the optical source 1010 and the adjusted optical characteristics of the optical structural parameters for the voxels 912 for the time step.

Each update operation is succeeded by another update operation, which are representative of successive steps forward in time within the plurality of time steps. For example, update operation 1016 updates the values (see, e.g., FIG. 10B) based on the electrical performance and field response determined from the previous update operation 1014, optical sources 1010, electrical sources 1058, and the structural parameters 1008. Similarly, update operation 1018 updates the values (see, e.g., FIG. 10B) based on the electrical performance and field response determined from update operation 1016. In other words, at each time step of the operational simulation the values are updated based on the previous values, the signals provided by the optical sources 1010 and electrical sources 1058, and structural parameters of the photonic device.

In some embodiments, the simulated behavior of the one or more electrical sources 1058 may change over time. For example, the one or more electrical sources 1058 may be simulated to generate a first signal that indicates a first logical value (e.g., a digital 1), transition to generating a second signal that indicates a second logical value (e.g., a digital 0), and back to generating the first signal that indicates the first logical value over time. In some embodiments, the first signal and second signal may have different voltages, frequencies, amplitudes, phases, or other characteristics. A clock speed at which the simulation changes the one or more electrical sources 1058 from generating the first signal to the second signal and back may be provided in the design specification. The design specification may also provide a pattern at which the signal should be changed (e.g., alternating directly between the first signal and second signal on consecutive clock cycles, simulating the first signal or the second signal on multiple consecutive clock cycles in a row before switching, etc.).

The simulation of the electrical performance based on the electrical structural parameters may include using a semiconductor simulator configured to take into structural considerations such as the dopant concentrations (P and N distributions, and/or other dopants) within the voxels of the electrically active region 120 to determine drift diffusion equation solutions, conduct a charge transport simulation, and/or perform other tasks to simulate an amount of effect generated on the optical characteristics of the optical structural parameters of the voxels of the optically active region 114. Any suitable semiconductor simulator may be used, including but not limited to COMSOL provided by COMSOL, Inc., DEVSIM provided by DEVSIM LLC, Synopsis provided by Synopsys, Inc., or any other semiconductor simulator. Other circuitry of the device, including but not limited to circuitry of one or more feed lines, circuitry of one or more pulse shaping networks, and/or any other electrical structure may be simulated using any suitable circuit simulator, including but not limited to SPICE from the University of California at Berkeley. In some embodiments, these commercially available solvers perform simulations via time steps similar to the FDTD simulation of the optical performance, and so the time steps for the simulation of electrical performance and optical performance may be synchronized.

Once the final time step of the operational simulation 1002 is performed, a performance loss function 1020 is used to determine a performance loss value 1022. Any suitable performance loss function 1020 and performance loss value 1022 may be used. Depending on a portion of the modulator device being designed, different performance loss functions 1020 and performance loss values 1022 may be used. For example, if a phase shifter is being designed in isolation, the performance loss function 1020 may measure a phase of the signal at the output port over time, and a comparison of the phase over time to a desired phase over time may be the performance loss value 1022. As another example, if the entire modulator device is being designed, the performance loss function 1020 may generate an interpretation of a modulated output over time at the output port, and a comparison of the modulated output over time to a desired modulated output over time may be the performance loss value 1022.

One non-limiting example of a technique that may be used to measure modulation performance is to determine and measure an eye diagram representing the modulated output. The performance loss function 1020 may compare the eye diagram to a desired eye diagram provided in the design specification, or may measure aspects of the eye diagram and attempt to maximize performance of the measured aspects.

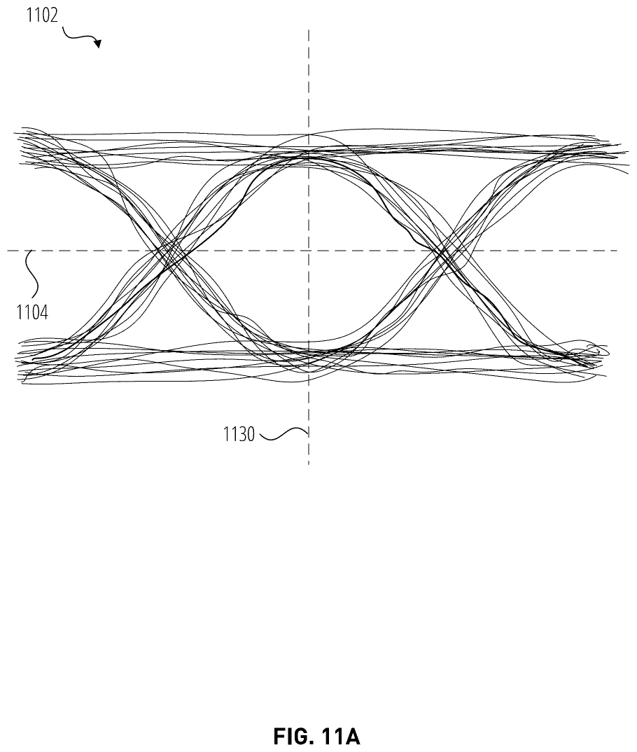

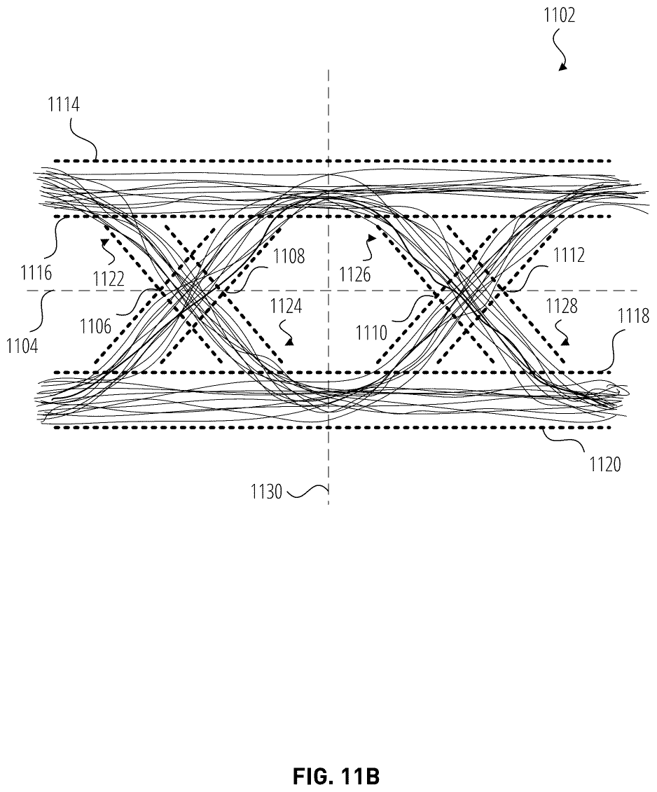

FIG. 11A illustrates a non-limiting example embodiment of an eye diagram according to various aspects of the present disclosure. The eye diagram 1102 illustrates logical values of an optical signal output at the output port, as measured by the performance loss function 1020 from the result of the operational simulation 1002. One of skill in the art will recognize the format of the eye diagram 1102, wherein signals received during multiple clock cycles are overlaid atop each other, with a sampling point 1130 representing a point in the clock cycle at which the performance loss function 1020 may determine the logical value. A zero line 1104 represents a middle of a range of voltage values sensed, with a first logical value being represented by values above the zero line 1104, and a second logical value being represented by values below the zero line 1104. Depending on the clock cycle, the signal either stays at its existing logical value, transitions from one logical value to the other, or transitions from one logical value too the other and back. While the eye diagram 1102 illustrates two logical states, in some embodiments, more logical states may be present, and the eye diagram 1102 may illustrate more than one clock cycle.

FIG. 11B adds annotations to the eye diagram 1102 in bold dashed lines to indicate features that may be measured by the performance loss function 1020 that reflect potential modulation performance of the physical device. A distance between a first line 1114 and a second line 1116 indicates an amount of distortion at a first logical value, and a distance between a third line 1118 and a fourth line 1120 indicates an amount of distortion at a second logical value. A distance between a first point 1106 and a second point 1108, and a distance between a third point 1110 and a fourth point 1112, indicate an amount of jitter, or an amount at which various clock cycles of the signal are different lengths compared to each other. A distance between the second line 1116 and the zero line 1104, and/or between the third line 1118 and the zero line 1104, represents a signal-to-noise ratio at the sampling point 1130. A slope of the transitions (i.e., the region between the first transition line 1122 and the second transition line 1124 that indicates a transition from the first logical value to the second logical value, and the region between the third transition line 1126 and the fourth transition line 1128 that indicates a transition from the second logical value to the first logical value) indicates an amount of time it takes to transition between the logical values.

The performance loss function 1020 may measure any desired aspect of the eye diagram 1102 to compare it to a desired value for optimization. For example, the performance loss function 1020 may measure the slope of the transitions, and may optimize to increase the slope of the transitions so that the physical device can successfully operate at greater clock rates for incoming signals. As another example, the performance loss function 1020 may measure the distances between the second line 1116 and the zero line 1104, and between the zero line 1104 and the third line 1118, in order to increase the distances and thereby improve the signal-to-noise ratio. These examples should not be seen as limiting, and in other embodiments, the performance loss function 1020 may measure other aspects of the eye diagram 1102. Further, the use and measurement of an eye diagram 1102 should not be seen as limiting. In other embodiments, different analyses of the simulated output of the modulator device, including but not limited to a BERT scan, may be used.

Returning to FIG. 10A, the performance loss value 1022 is converted into a loss metric 1024. The loss metric 1024 is a value to be minimized that represents at least a difference between the simulated performance of the physical device and the desired performance of the physical device. In some embodiments, additional factors may be included in the loss metric 1024, including but not limited to one or more of a measure of the fabricability of the physical device, a measure of heat generated by the physical device, an amount of power lost or used by the physical device, or any other aspect of the physical device that it is desired to be optimized.

From the loss metric 1024, a gradient of the performance loss function may be determined at block 1026. The gradient determined from block 1026 is treated as an adjoint input to the operational simulation, and an adjoint simulation 1004 is performed. In some embodiments, if a differentiable simulator is used for simulating various aspects of the electronic components, the gradient provided by the differentiable simulator may be used for the adjoint simulation 1004. The adjoint simulation 1004 produces a structural gradient 1034, which indicates changes to be made to the structural parameters 1008 (including the optical structural parameters and the electrical structural parameters) in order to improve performance of the physical device, given the simulated values calculated during the operational simulation 1002.

The result of the adjoint simulation 1004, in turn, may be backpropagated in reverse (from the final time step incrementally through the plurality of time steps until reaching the initial time step via update operation 1028, update operation 1032, and update operation 1030) to determine the structural gradient 1034 that indicates changes to be made to the structural parameters 1008 to further improve performance.

In the illustrated embodiment, the operational simulation 1002 and the adjoint simulation 1004 are described pictorially, from a high-level, using “update” and “loss” operations as well as their corresponding gradient operations. The simulation is set up initially in which the structural parameters, physical stimuli (i.e., optical source and electrical source), and initial field states of the simulated environment (and photonic device) are provided (e.g., via an initial description and/or input design). As discussed previously, the field values and electrical performance are updated in response to the optical source and the electrical source based on the structural parameters. More specifically, the update operation is given by ϕ, where xᵢ₊₁=ϕ(xᵢ, [symbol] ᵢ, z) for i=1, . . . , n. Here, n corresponds to the total number of time steps (e.g., the plurality of time steps) for the operational simulation, where xᵢ corresponds to the field response (the field value associated with the electric and magnetic fields of each of the plurality of voxels) of the simulated environment at time step i, [symbol] ᵢ corresponds to the optical source(s) (the source value associated with the electric and magnetic fields for each of the plurality of voxels) and electrical source(s) of the simulated environment at time step i, and z corresponds to the structural parameters describing the topology and/or material properties of the physical device (e.g., relative permittivity, index of refraction, and the like).

It is noted that using the FDTD method, the update operation may specifically be stated as:

$$ϕ ( {x}_{i} , {b}_{i} , z ) = A ( z ) {x}_{i} + B ( z ) {b}_{i} . \qquad Equation 1$$

That is to say the FDTD update is linear with respect to the field and source terms. Concretely, A(z)∈ [symbol] ^{N×N} and B(z)∈ [symbol] ^{N×N} are linear operators which depend on the structure parameters, z, and act on the fields, xᵢ, and the sources, [symbol] ᵢ, respectively. Here, it is assumed that xᵢ, [symbol] ᵢ∈ [symbol] ^{N} where N is the number of FDTD field components in the operational simulation. Additionally, the loss operation (e.g., loss function) may be given by L=ƒ(xᵢ, . . . , xₙ), which takes as input the eye diagram (and/or other measurements of performance or fitness) and produces a single, real-valued scalar (e.g., the loss metric) that can be reduced and/or minimized.

In terms of revising or otherwise optimizing the structural parameters of the physical device, the relevant quantity to produce is dL/dz, which is used to describe the influence of changes in the structural parameters of the initial design 1036 on the loss value and is denoted as the structural gradient 1034 illustrated in FIG. 10A.

FIG. 10B is a chart 1038 illustrating the relationship between the update operation for the operational simulation and the adjoint simulation (e.g., backpropagation), in accordance with an embodiment of the present disclosure. More specifically, FIG. 10B summarizes the operational and adjoint simulation relationships that are involved in computing the structural gradient for the optical structural parameters, dL/dz, which include

$$\frac{\partial L}{\partial {x}_{i}} , \frac{\partial {x}_{i + 1}}{\partial {x}_{i}} , \frac{dL}{{dx}_{i}} , and \frac{\partial {x}_{i}}{\partial z} .$$

Additional terms may be added to represent the structural gradient for the electrical structural parameters.

The update operation 1016 of the operational simulation 1002 updates the field values 1040, xᵢ, of the plurality of voxels at the ith time step to the next time step (i.e., i+1 time step), which correspond to the field values 1042, xᵢ₊₁. The gradient 1044 are utilized to determine

$$\frac{\partial L}{\partial {x}_{i}}$$

for the backpropagation (e.g., update operation 1032 backwards in time), which combined with the gradient 1046 are used, at least in part, to calculate the structural gradient,

$$\frac{dL}{dz} \cdot \frac{\partial L}{\partial {x}_{i}}$$

is the contribution of each field to the loss metric, L. It is noted that this is the partial derivative, and therefore does not take into account the causal relationship of xᵢ→xᵢ₊₁. Thus,

$$\frac{\partial {x}_{i + 1}}{\partial {x}_{i}}$$

is utilized which encompasses the xᵢ→xᵢ₊₁ relationship. The loss gradient,

$$\frac{dL}{d {x}_{i}} ,$$

may also be used to compute the structural gradient, dL/dz, and corresponds to the total derivative of the field with respect to loss value, L. The loss gradient,

$$\frac{dL}{d {x}_{i}} ,$$

at a particular time step, i, is equal to the summation of

$$\frac{\partial L}{\partial {x}_{i}} + \frac{dL}{{dx}_{i + 1}} \frac{\partial {x}_{i + 1}}{\partial {x}_{i}} .$$

### Finally,

$$\frac{\partial {x}_{i}}{\partial z} ,$$

which corresponds to the field gradient, is used which is the contribution to dL/dz from each time/update step.

In particular, the memory footprint to directly compute

$$\frac{\partial L}{\partial {x}_{i}} and \frac{dL}{dz}$$

large that it is difficult to store more than a handful of state Tensors. The state Tensor corresponds to storing the values of all of the FDTD cells (e.g., the plurality of voxels) for a single simulation time step. It is appreciated that the term “tensor” may refer to tensors in a mathematical sense or as described by the TensorFlow framework developed by Alphabet, Inc. In some embodiments the term “tensor” refers to a mathematical tensor which corresponds to a multidimensional array that follows specific transformation laws. However, in most embodiments, the term “tensor” refers to TensorFlow tensors, in which a tensor is described as a generalization of vectors and matrices to potentially higher dimensions (e.g., n-dimensional arrays of base data types), and is not necessarily limited to specific transformation laws. For example, for the general loss function ƒ, it may be desired to store the fields, xᵢ, for all time steps, i. This is because, for most choices of ƒ, the gradient will be a function of the arguments of ƒ. This difficulty is compounded by the fact that the values of

$$\frac{\partial L}{\partial {x}_{i}}$$

for larger values of i are needed before the values for smaller i due to the incremental updates of the field response and/or through backpropagation of the loss metric, which may prevent the use of schemes that attempt to store only the values

$$\frac{\partial L}{\partial {x}_{i}} ,$$

at an immediate time step.

An additional difficulty is further illustrated when computing the structural gradient, dL/dz, which is given by:

$$\frac{d L}{d z} = {\sum }_{i} \frac{d L}{d {x}_{i}} \frac{\partial {x}_{i}}{\partial z} . \qquad Equation 2.$$

For completeness, the full form of the first term in the sum, dL/dz, is expressed as:

$$\frac{dL}{{dx}_{i}} = \frac{\partial L}{\partial {x}_{i}} + \frac{dL}{{dx}_{i + 1}} \frac{\partial {x}_{i + 1}}{\partial {x}_{i}} . \qquad Equation 3$$

Based on the definition of § as described by equation (1), it is noted that

$$\frac{\partial {x}_{i + 1}}{\partial {x}_{i}} = A ( z ) ,$$

which can be substituted in equation (3) to arrive at an adjoint update for backpropagation (e.g., the update operations such as update operation 1032), which can be expressed as:

$$\frac{dL}{{dx}_{i}} = \frac{\partial L}{\partial {x}_{i}} + \frac{dL}{{dx}_{i + 1}} A ( z ) , \qquad Equation 4.$$

$$or$$

$${∇}_{{x}_{i}} L = {A ( z )}^{T} {∇}_{{x}_{i + 1}} L + \frac{\partial {L}^{T}}{\partial {x}_{i}} . \qquad Equation 5$$

The adjoint update is the backpropagation of the loss gradient (e.g., from the loss metric) from later to earlier time steps and may be referred to as a backwards solve for

$$\frac{dL}{{dx}_{i}} .$$

More specifically, the loss gradient may initially be based upon the backpropagation of a loss metric determined from the operational simulation with the loss function. The second term in the sum of the structural gradient, dL/dz, corresponds to the field gradient and is denoted as:

$$\frac{\partial {x}_{i}}{\partial z} = \frac{d ϕ ( {x}_{i - 1} , {b}_{i - 1} , z )}{dz} = \frac{dA ( z )}{dz} {x}_{i - 1} + \frac{dB ( z )}{dz} {b}_{i - 1} , \qquad Equation 6.$$

for the particular form of ϕ described by the first equation above. Thus, each term of the sum associated dL/dz depends on both

$$\frac{dL}{{dx}_{{i}_{0}}}$$

for i>=i₀ and xᵢ_{₀} for i<i₀. Since the dependency chains of these two terms are in opposite directions, it is concluded that computing dL/dz in this way utilizes the storage of xᵢ values for all of i. In some embodiments, the need to store all field values may be mitigated by a reduced representation of the fields.

While the embodiments described above contemplate a combined optical and electrical simulation along with a combined optical and electrical update, in other embodiments, these actions may be performed sequentially, and a derived coupling term may be used to cause gradients to flow through both designs. For example, a charge transport simulation may be performed first to solve for charge carrier distributions within the electrically active region, and the charge carrier distributions may be used as a loss term in the FDTD simulation of the optically active region.

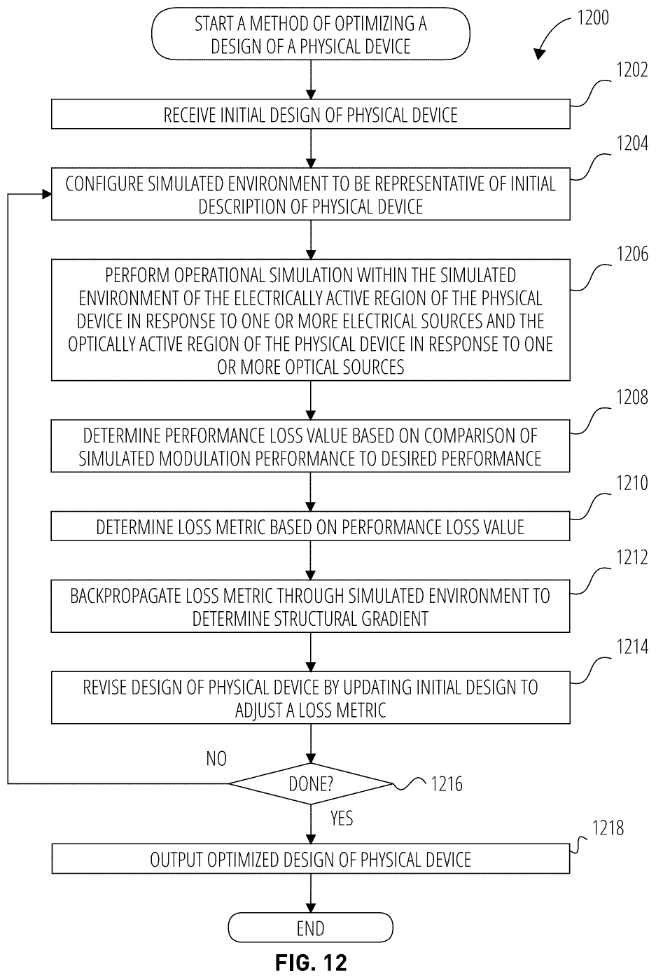

FIG. 12 is a flowchart that illustrates a non-limiting example embodiment of a method for generating a design of physical device such as a photonic integrated circuit, in accordance with various aspects of the present disclosure. It is appreciated that method 1200 is an inverse design process that may be accomplished by performing operations with a system to perform iterative gradient-based optimization of a loss metric determined from a loss function that includes at least a performance loss. In the same or other embodiments, method 1200 may be included as instructions provided by at least one machine-accessible storage medium (e.g., non-transitory memory) that, when executed by a machine or a collection of machines (e.g., computing system 800), will cause the machine(s) to perform operations for generating and/or improving the design of the photonic integrated circuit. It is further appreciated that the order in which some or all of the process blocks appear in method 1200 should not be deemed limiting. Rather, one of ordinary skill in the art having the benefit of the present disclosure will understand that some of the process blocks may be executed in a variety of orders not illustrated, or even in parallel.

From a start block, the method 1200 proceeds to block 1202, where an initial design 1036 of a physical device such as a photonic integrated circuit is received. In some embodiments, the physical device may be expected to have a certain functionality (e.g., perform as an optoelectronic modulator device or a component of an optoelectronic modulator device such as a phase shifter) after optimization. The initial design 1036 may describe structural parameters of the physical device within a simulated environment. The simulated environment may include a plurality of voxels that collectively describe the structural parameters of an optically active region 114 (optical structural parameters) and an electrically active region 120 (electrical structural parameters) of the physical device. Each of the plurality of voxels is associated with a structural value to describe the structural parameters, a field value to describe the field response (e.g., the electric and magnetic fields in one or more orthogonal directions) to physical stimuli (e.g., one or more optical sources 1010 and electrical sources 1058), and a source value to describe the physical stimuli (e.g., a wavelength of an incoming optical signal; a frequency/voltage/etc of an incoming electrical signal; etc.). The initial design 1036 and/or structural parameters may also include information regarding other aspects of circuitry associated with the electrically active region 120, including but not limited the shape/size/location/number of one or more feed lines or electrodes; and/or the location and configuration of one or more pulse shaping networks.

In some embodiments the initial design 1036 may be a first description of the physical device in which values for the structural parameters may be random values or null values such that there is no bias for the initial (e.g., first) design. It is appreciated that the initial description or input design may be a relative term. Thus, in some embodiments an initial description may be a first description of the physical device described within the context of the simulated environment (e.g., a first input design for performing a first operational simulation).

However, in other embodiments, the term initial description may refer to an initial description of a particular cycle (e.g., of performing an operational simulation 1002, operating an adjoint simulation 1004, and updating the structural parameters). In such an embodiment, the initial design 1036 or design of that particular cycle may correspond to a revised description or refined design (e.g., generated from a previous cycle). In some embodiments, the simulated environment includes a design region that includes a portion of the plurality of voxels which have structural parameters that may be updated, revised, or otherwise changed to optimize the structural parameters of the physical device. In the same or other embodiments, the structural parameters are associated with geometric boundaries and/or material compositions of the physical device based on the material properties (e.g., relative permittivity, index of refraction, etc.) of the simulated environment.

At block 1204, a simulated environment is configured to be representative of the initial description (e.g., the structural parameters based on the initial design) of the physical device. Once the structural parameters have been received or otherwise obtained, the simulated environment is configured (e.g., the number of voxels, shape/arrangement of voxels, and specific values for the structural value, field value, and/or source value of the voxels for the optically active region 114 are set based on the optical structural parameters; and the doped regions of the electrically active region 120, as well as the size, shape, and location of contact points/electrodes and other circuitry are set based on the electrical structural parameters). In some embodiments the simulated environment includes a design region (e.g., the optically active region 114 and at least a portion of the electrically active region 120) optically coupled to at least a first communication region. In some embodiments, the first communication region may correspond to an input region or port (e.g., where an optical source originates).

Block 1206 illustrates performing an operational simulation within the simulated environment of the electrically active region 120 of the physical device in response to the one or more electrical sources 1058 and the optically active region 114 of the physical device in response to the one or more optical sources 1010. More specifically, in some embodiments an electromagnetic simulation is performed in which the electrical performance of the electrically active region 120 is updated incrementally over a plurality of time steps in response to the one or more electrical sources 1058 in order to adjust optical characteristics of the optical structural parameters, and a field response of the photonic integrated circuit is updated incrementally over a plurality of time steps to determine how the how the field response of the physical device changes due to the one or more optical sources 1010 and the adjustments to the optical characteristics. The field values of the plurality of voxels are updated in response to the optical source and based, at least in part, on the structural parameters of the optically active region 114 and the adjusted optical characteristics. Additionally, each update operation at a particular time step may also be based, at least in part, on a previous (e.g., immediately prior) time step. Further, the action of the one or more electrical sources 1058 may change over time (e.g., representing modulation between a signal representing a first logical value and a signal representing a second logical value). In some embodiments, the time steps may be calculated congruently (i.e., a given time step may be calculated for the electrical performance and then the optical performance before moving on to the next time step). In some embodiments, multiple time steps for the simulation of the electrical performance may be completed in order to determine the adjusted optical characteristics for the time steps prior to calculating the corresponding time steps for the optical performance.

Consequently, the operational simulation simulates an interaction between the photonic device (i.e., the optically active region 114 and the electrically active region 120) and a physical stimuli (i.e., one or more electrical sources 1058 and one or more optical sources 1010) to determine simulated field values within the optically active region 114 in response to the physical stimuli. The interaction may correspond to any one of, or combination of a perturbation, retransmission, attenuation, dispersion, refraction, reflection, diffraction, absorption, scattering, amplification, or otherwise of the physical stimuli within electromagnetic domain due, at least in part, to the structural parameters of the photonic device (as adjusted as a result of the simulation of the electrically active region 120) and underlying physics governing operation of the photonic device. Thus, the operational simulation simulates how the field response of the simulated environment changes due to the optical source(s) and the electrical source(s) over a plurality of time steps (e.g., from an initial to final time step with a pre-determined step size).

Block 1208 illustrates determining a performance loss value based on comparison of the simulated modulation performance to a desired performance. In some embodiments, the simulated modulation performance (i.e., a phase, amplitude, or other characteristic of the signal output at the output port 904, in comparison to an expected characteristic based on the input electrical signal) may be utilized to determine one or more performance metrics of the physical device. For example, as discussed above, an eye diagram representing the simulated modulated signal may be compared to a desired eye diagram, or characteristics of the eye diagram may be measured and compared to desired characteristics.

Block 1210 shows determining a loss metric based on the performance loss value. In some embodiments the loss metric is determined via a loss function that includes the performance loss value as input values. Other values, including but not limited to fabrication loss values (a value indicating whether the design is fabricable), may be combined with the performance loss value in creating the loss metric.

Block 1212 illustrates backpropagating the loss metric via the loss function through the simulated environment to determine an influence of changes in the structural parameters on the loss metric (i.e., structural gradient). The loss metric may be treated as an adjoint or virtual source, and may be backpropagated incrementally from a final time step to earlier time steps in a backwards simulation to determine the structural gradient of the physical device.

Block 1214 shows revising a design of the physical device (e.g., generated a revised description) by updating the structural parameters of the initial design 1036 to adjust the loss metric. In some embodiments, adjusting for the loss metric may reduce the loss metric. However, in other embodiments, the loss metric may be adjusted or otherwise compensated in a manner that does not necessarily reduce the loss metric. In some embodiments, the revised description is generated by utilizing an optimization scheme after a cycle of operational and adjoint simulations via a gradient descent algorithm, Markov Chain Monte Carlo algorithm, Adam optimizer, or other optimization techniques. Put in another way, iterative cycles of simulating the physical device, determining a loss metric, backpropagating the loss metric, and updating the structural parameters to adjust the loss metric may be successively performed until the loss metric substantially converges such that the difference between the performance metric and the target performance metric is within a threshold range.

It should be appreciated that, in some embodiments, the changes to the electrical structural parameters may affect more than the size, shape, and/or location of a doped region, a conductor, or other aspects specified by the electrical structural parameters. For example, the changes to the electrical structural parameters may add or remove doped regions in order to more efficiently couple the electrical effects to the waveguide, and/or may add or remove electrodes, feed lines, pulse shaping networks, or other circuitry in order to further improve the loss metric. In some embodiments, separate values may be tracked to represent the existence of the addable/removable characteristics, and an estimator may be used to pass gradients through to these values during the updates in order to cause the characteristics to be added or removed.

One will note that any suitable parameterization of the structural parameters may be used. In some embodiments, the electrical structural parameters may be adjusted separately for each voxel (e.g., an identity of a dopant used or a lack of dopant may be specified separately for each voxel; a presence or absence of conductive material may be specified separately for each voxel; etc.), as may the optical structural parameters (e.g., a presence of a first material or a second material may be specified separately for each voxel). In some embodiments, the structural parameters may be provided as real values indicating a position between possible values to be simulated, and a step of discretization may be performed to convert the real values to discrete values prior to configuring the simulated environment. In some embodiments, the structural parameters may be parameterized with fewer degrees of freedom in order to increase the efficiency of the simulation and the optimization. For example, one or more of the structural parameters may be parameterized as geometric shapes (e.g., circles, squares, polygons, or any other geometric shape) at a lower resolution than the voxels, and adjustments to the structural parameters may cause changes to the position, size, and/or number of the geometric shapes.

In some embodiments, the electrical structural parameters may be further constrained into a general design, which provides a limited number of degrees of freedom for adjustment. For example, the general design of the transmission line phase shifter 502 of FIG. 5 may be retained by not allowing adjustments to the shape of the first transmission line 508 and the second transmission line 514, but adjustments may nevertheless be made by changing the width/height/depth of the first transmission line 508 and/or the second transmission line 514, by changing a distance between the first transmission line 508 and/or the second transmission line 514 and the waveguide 506, by changing the location/length/etc. of the feed line 510, by adding or removing one or more additional feed lines 518, by adding or removing a pulse shaping network, etc. As another example, the general design of the interdigitated phase shifter 602 illustrated in FIG. 6A may be retained while nevertheless allowing adjustments to the height/width/depth of the first highly doped region 604, first doped region 606, second doped region 608, and/or second highly doped region 610; the depth to which the first doped region 606 and second doped region 608 are interdigitated; the frequency at which the first doped region 606 and second doped region 608 are interdigitated; etc. Likewise, as yet another example, the general designs of the horizontally arranged phase shifter 614 or vertically arranged phase shifter 632 may be retained while nevertheless allowing adjustments to the height/width/depth/cross-sectional shape of the doped regions; the number and/or position of the electrodes; etc.

At decision block 1216, a determination is made regarding whether the further iterations should be performed, or whether the method 1200 is done optimizing the physical device. In some embodiments, iterative cycles of simulating the physical device with the optical source(s) and electrical source(s), backpropagating the loss metric, and revising the design by updating the structural parameters are performed to reduce the loss metric until the loss metric substantially converges such that the difference between the performance metric and the target performance metric is within a threshold range. In some embodiments, the method 1200 performs a predetermined number of iterations.

If the determination is that further iterations should be performed, then the result of decision block 1216 is NO, and the method 1200 returns to block 1204 to iterate on the revised initial design 1036. Otherwise, if the determination is that the loss metric has converged, then the result of decision block 1216 is YES and the method 1200 advances to block 1218.

Block 1218 illustrates outputting an optimized design of the physical device in which the structural parameters have been updated to have the difference between the performance metric and the target performance metric optimized. The method 1200 then proceeds to an end block and terminates. This optimized design may be in a format, or convertible to a format, that may be transmitted to a foundry for fabrication of a physical device implementing the optimized design. In some embodiments, the optimized design may be (or may be used to generate) a description (e.g., layout data, netlist data, modeling/simulation data, etc.) of the physical device. The description may be incorporated into a software library of integrable components for optoelectronic modular devices or may otherwise be used by computer-aided design tools.

One will recognize that various changes can be made to the method 1200 without departing from the scope of the present disclosure. For example, in some embodiments, the optical structural parameters may be kept constant, and updates may only be applied to the electrical structural parameters, or vice versa. As another example, in some embodiments, the method 1200 may alternate between updating the optical structural parameters for one or more iterations and then updating the electrical structural parameters for one or more iterations, or may use different learning rates for the updates to the optical structural parameters and the electrical structural parameters, to improve the likelihood that the design will converge to an optimal value.

In the preceding description, numerous specific details are set forth to provide a thorough understanding of various embodiments of the present disclosure. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

The order in which some or all of the blocks appear in each method flowchart should not be deemed limiting. Rather, one of ordinary skill in the art having the benefit of the present disclosure will understand that actions associated with some of the blocks may be executed in a variety of orders not illustrated, or even in parallel.

The processes explained above are described in terms of computer software and hardware. The techniques described may constitute machine-executable instructions embodied within a tangible or non-transitory machine (e.g., computer) readable storage medium, that when executed by a machine will cause the machine to perform the operations described. Additionally, the processes may be embodied within hardware, such as an application specific integrated circuit (“ASIC”) or otherwise.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific embodiments disclosed in the specification. Rather, the scope of the invention is to be determined entirely by the following claims, which are to be construed in accordance with established doctrines of claim interpretation.

What is claimed is:

1. A non-transitory computer-readable medium having logic stored thereon that, in response to execution by one or more processors of a computing system, causes the computing system to perform actions for creating a design for an optoelectronic modulator device, the actions comprising:
determining, by the computing system, an initial design that includes optical structural parameters and electrical structural parameters for a design region;
simulating, by the computing system, electrical performance based on the electrical structural parameters to adjust optical characteristics of the optical structural parameters;
simulating, by the computing system, optical performance of the optical structural parameters having the adjusted optical characteristics to generate a performance loss value;
determining, by the computing system, a loss metric based on the performance loss value;
backpropagating, by the computing system, the loss metric to determine a structural gradient; and
revising, by the computing system, at least one of the optical structural parameters and the electrical structural parameters based at least in part on the structural gradient to create an updated initial design.

2. The non-transitory computer-readable medium of claim 1, wherein the actions further comprise:
repeating the simulating electrical performance based on the electrical structural parameters to adjust optical characteristics of the optical structural parameters, simulating optical performance of the optical structural parameters having the adjusted optical characteristics to generate a performance loss value, determining the loss metric, backpropagating the loss metric to determine the structural gradient, and revising at least one of the optical structural parameters and the electrical structural parameters based at least in part on the structural gradient to further update the updated initial design.

3. The non-transitory computer-readable medium of claim 1, wherein the electrical structural parameters include a shape and a location of at least one doped region; and
wherein revising the electrical structural parameters includes changing at least one of the shape and the location of the at least one doped region.

4. The non-transitory computer-readable medium of claim 1, wherein the electrical structural parameters include a shape and a location of at least one conductor; and
wherein revising the electrical structural parameters includes changing at least one of the shape and the location of the at least one conductor.

5. The non-transitory computer-readable medium of claim 1, wherein simulating electrical performance based on the electrical structural parameters to adjust optical characteristics of the optical structural parameters includes:
simulating charge distribution behavior in response to an electrical signal; and
adjusting a refractive index of the optical structural parameters based on the charge distribution behavior.

6. The non-transitory computer-readable medium of claim 1, wherein the performance loss value includes a measurement of an output value measured at an output region.

7. The non-transitory computer-readable medium of claim 6, wherein the measurement of the output value measured at the output region includes a characteristic of an eye diagram; and
wherein determining the loss metric based on the performance loss value includes comparing the characteristic of the eye diagram to a desired characteristic of the eye diagram.

8. The non-transitory computer-readable medium of claim 7, wherein the characteristic of the eye diagram represents an amount of time to transition between logical states.

9. The non-transitory computer-readable medium of claim 7, wherein the characteristic of the eye diagram represents a signal-to-noise ratio.

10. The non-transitory computer-readable medium of claim 1, wherein at least a portion of the electrical structural parameters and a portion of the optical structural parameters overlap within the design region in one or more dimensions.

11. A computer-implemented method for creating a design for an optoelectronic modulator device, the method comprising:
determining, by a computing system, an initial design that includes optical structural parameters and electrical structural parameters for a design region;
simulating, by the computing system, electrical performance based on the electrical structural parameters to adjust optical characteristics of the optical structural parameters;
simulating, by the computing system, optical performance of the optical structural parameters having the adjusted optical characteristics to generate a performance loss value;
determining, by the computing system, a loss metric based on the performance loss value;
backpropagating, by the computing system, the loss metric to determine a structural gradient; and
revising, by the computing system, at least one of the optical structural parameters and the electrical structural parameters based at least in part on the structural gradient to create an updated initial design.

12. The computer-implemented method of claim 11, wherein the method further comprises:
repeating the simulating electrical performance based on the electrical structural parameters to adjust optical characteristics of the optical structural parameters, simulating optical performance of the optical structural parameters having the adjusted optical characteristics to generate a performance loss value, determining the loss metric, backpropagating the loss metric to determine the structural gradient, and revising at least one of the optical structural parameters and the electrical structural parameters based at least in part on the structural gradient to further update the updated initial design.

13. The computer-implemented method of claim 11, wherein the electrical structural parameters include a shape and a location of at least one doped region; and
wherein revising the electrical structural parameters includes changing at least one of the shape and the location of the at least one doped region.

14. The computer-implemented method of claim 11, wherein the electrical structural parameters include a shape and a location of at least one conductor; and
wherein revising the electrical structural parameters includes changing at least one of the shape and the location of the at least one conductor.

15. The computer-implemented method of claim 11, wherein simulating electrical performance based on the electrical structural parameters to adjust optical characteristics of the optical structural parameters includes:
simulating charge distribution behavior in response to an electrical signal; and
adjusting a refractive index of the optical structural parameters based on the charge distribution behavior.

16. The computer-implemented method of claim 11, wherein the performance loss value includes a measurement of an output value measured at an output region;
wherein the measurement of the output value measured at the output region includes a characteristic of an eye diagram; and
wherein determining the loss metric based on the performance loss value includes comparing the characteristic of the eye diagram to a desired characteristic of the eye diagram.

17. The computer-implemented method of claim 16, wherein the characteristic of the eye diagram represents an amount of time to transition between logical states.

18. The computer-implemented method of claim 16, wherein the characteristic of the eye diagram represents a signal-to-noise ratio.

19. The computer-implemented method of claim 11, wherein at least a portion of the electrical structural parameters and a portion of the optical structural parameters overlap within the design region in one or more dimensions.

20. A non-transitory computer-readable medium having a description stored thereon that represents structures within a design region of an optoelectronic modulator device, wherein the description is determined by:
determining, by a computing system, an initial design that includes optical structural parameters and electrical structural parameters for the design region;
simulating, by the computing system, electrical performance based on the electrical structural parameters to adjust optical characteristics of the optical structural parameters;
simulating, by the computing system, optical performance of the optical structural parameters having the adjusted optical characteristics to generate a performance loss value;
determining, by the computing system, a loss metric based on the performance loss value;
backpropagating, by the computing system, the loss metric to determine a structural gradient; and
revising, by the computing system, at least one of the optical structural parameters and the electrical structural parameters based at least in part on the structural gradient to create an updated initial design.
